(19) United States
(12) Patent Application Publication
(10) Pub. No.: US 2013/0181893 A1
(43) Pub. Date: Jul. 18, 2013

(54) ELECTROSTATICALLY TRANSDUCED SENSORS COMPOSED OF PHOTOCHEMICALLY ETCHED GLASS

(71) Applicants: Justin Phelps Black, Santa Clara, CA (US); Ravindra V. Shenoy, Dublin, CA (US); Jon Bradley Lasiter, Stockton, CA (US); Philip Jason Stephanou, Mountain View, CA (US)

(72) Inventors: Justin Phelps Black, Santa Clara, CA (US); Ravindra V. Shenoy, Dublin, CA (US); Jon Bradley Lasiter, Stockton, CA (US); Philip Jason Stephanou, Mountain View, CA (US)

(73) Assignee: QUALCOMM MEMS TECHNOLOGIES, INC., San Diego, CA (US)

(21) Appl. No.: 13/449,198

(22) Filed: Apr. 17, 2012

Related U.S. Application Data
(60) Provisional application No. 61/586,673, filed on Jan. 13, 2012.

(51) Int. Cl. G06T 1/00; H05K 3/00; G06F 3/01; G01L 1/10; G06F 3/038

(52) U.S. Cl. 345/156; 73/862.59; 345/501; 216/18

(57) ABSTRACT

This disclosure provides systems, methods and apparatus for glass electromechanical systems (EMS) electrostatic devices. In one aspect, a glass EMS electrostatic device includes sidewall electrodes. Structural components of a glass EMS electrostatic device such as stationary support structures, movable masses, coupling flexures, and sidewall electrode supports, can be formed from a single glass body. The glass body can be a photochemically etched. In some implementations, pairs of sidewall electrodes can be arranged in interdigitated comb or parallel plate configurations and can include plated metal layers and narrow capacitive gap spacing.

### CROSS-REFERENCE TO RELATED APPLICATION

This application claims the benefit under 35 U.S.C. §119(e) of U.S. Provisional Application 61/586,673 titled “ELECTROSTATICALLY TRANSDUCED SENSORS COMPOSED OF PHOTOCHEMICALLY ETCHED GLASS,” filed Jan. 13, 2012, all of which is incorporated herein in its entirety by this reference.

### TECHNICAL FIELD

This disclosure relates generally to electromechanical systems (EMS) devices and more particularly to EMS electrostatically transduced sensors.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

EMS devices also may be implemented as inertial sensors. EMS inertial sensors can be used to detect or measure motion including acceleration, vibration, shock, tilt and rotation. EMS inertial sensors have a wide range of applications, and may be used in products such as medical devices, consumer electronics, and automotive electronics.

### SUMMARY

The systems, methods and devices of the disclosure each have several innovative aspects, no single one of which is solely responsible for the desirable attributes disclosed herein.

One innovative aspect of this disclosure can be implemented in glass EMS electrostatic devices including sidewall electrodes. Structural components of a glass EMS electrostatic device, such as stationary support structures, movable masses, coupling flexures, and sidewall electrode supports, can be formed from a single glass body. The glass body can be photochemically etched. In some implementations, pairs of sidewall electrodes can be arranged in interdigitated comb or parallel plate configurations and can include plated metal layers and narrow capacitive gap spacing.

One innovative aspect of the subject matter described in this disclosure can be implemented in an apparatus including a glass body, the glass body including a movable mass, a support structure, and a plurality of sidewalls. The apparatus can further include one or more electrode pairs formed on the plurality of sidewalls. The movable mass and the support structure can be capacitively coupled by the one or more electrode pairs such that movement of the movable mass is detectable by a change in capacitance between one or more electrode pairs and/or movement of the movable mass can be induced by application of an electrostatic force to one or more electrode pairs.

In some implementations, the plurality of sidewalls can extend through the glass body. The height of each sidewall can be, for example, between about 50 microns and 1 mm. In some implementations, the gap between electrodes of an electrode pair can be no more than about 2 microns. In some implementations, the electrode pairs can be interdigitated electrode pairs.

The glass body can further include coupling flexures attaching the movable mass to the support structure. The coupling flexures can be, for example, S-shaped or U-shaped. In some implementations, the movable mass can include a plurality of coupled masses. The apparatus can further include one or more through-glass via interconnects that extend through the glass body.

Another innovative aspect of the subject matter described in this disclosure can be implemented in a method of fabricating glass EMS electrostatic devices. The method can include masking a glass substrate, treating unmasked areas of the glass substrate, and etching the treated areas of the glass substrate. Etching the treated areas can form a glass body including a movable mass, a support structure, and one or more pairs of sidewall electrode supports. The method can further include conformally coating the sidewalls of each pair of sidewall electrode supports with a conductive thin film to form one or more pairs of sidewall electrodes.

Treating the glass substrate can include exposing it to ultraviolet (UV) light and thermal annealing. Conformally coating the sidewalls can include a technique such as atomic layer deposition (ALD) or electroless plating, for example. In some implementations the conductive thin film can be plated to narrow a gap between adjacent sidewall electrodes.

In some implementations, the method can include partially etching the glass substrate to form one or more trenches. At least a bottom surface of each trench can remain free of the conductive thin film after conformally coating the sidewalls of the sidewall electrode supports. In some implementations, the method can include etching the glass substrate to define electrode isolation regions and filling the electrode isolation regions with a sacrificial material. The sacrificial material can be removed after conformally coating the sidewalls with the conductive thin film.

In some implementations, etching the treated areas of the glass substrate can include forming a plurality of glass bodies each including movable mass, a support structure, and one or more pairs of sidewall electrode supports. The glass bodies can be singulated into individual dies after further processing. In some implementations, individual dies can be further packaged.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows an example of a schematic illustration of a top view of a glass electromechanical systems (EMS) electrostatic structure.

FIG. 9B shows an example of a cross-sectional schematic illustration of a glass EMS electrostatic structure including sidewall electrodes.

FIGS. 10 and 11 show examples of flow diagrams illustrating manufacturing processes for glass EMS electrostatic structures.

FIGS. 12A-12D show examples of schematic illustrations of various stages in a method of making a glass EMS electrostatic structure.

FIGS. 13A and 13B show examples of schematic illustrations of an electrical isolation trench at various stages in a manufacturing process.

FIG. 14 shows an example of a flow diagram illustrating a manufacturing process for a glass EMS electrostatic structure.

FIGS. 15A-15G show examples of schematic illustrations of various stages in a method of making a glass EMS electrostatic structure.

FIGS. 16A and 16B show examples of schematic illustrations of plan views of an electrical isolation segment at various stages in a manufacturing process.

FIGS. 17A-17C show examples of schematic illustrations of a packaged die including a glass EMS electrostatic device.

FIGS. 18A and 18B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein related to glass EMS electrostatic devices and structures. The glass EMS electrostatic devices can include accelerometers, gyroscopes, oscillators and other resonant sensors. The glass EMS electrostatic structures can include an etched glass body, including a support structure and movable mass, and sidewall electrode pairs. In some implementations, the glass EMS electrostatic structure is a photochemically etched glass structure having a high aspect ratio through a glass substrate having a thickness of up to 1 mm. Structural components of the glass EMS electrostatic structure can include a support structure, a movable mass, coupling flexures that tether the movable mass to the support structure, and sidewall electrode supports. These structural components can all be formed from a single glass body. The sidewall electrode supports can be metallized to form sidewall electrode pairs having a high aspect ratio and small capacitive gaps. Metallization can include conformal conductive thin films and/or thicker plated metal layers. A thicker plated metal layer can reduce the capacitive gap spacing. Electrical isolation between regions of the device can be achieved, for example, by narrow trenches that prevent the formation of a continuous conductive coating or by lift-off sacrificial techniques.

Some implementations relate to batch panel-level methods of fabricating multiple glass EMS electrostatic devices. The methods can include wafer or panel-level etch and metallization processes to form movable masses, sidewall electrodes and other components of multiple glass EMS electrostatic devices, followed by singulation to form individual dies each including a glass EMS electrostatic device.

Particular implementations of the subject matter described in this disclosure can be implemented to realize one or more of the following potential advantages. In some implementations, the glass EMS electrostatic devices include high aspect ratio sidewall electrodes with small capacitive gap spacing between adjacent sidewall electrodes. The capacitive gap spacing can be reduced in some implementations by plating the sidewall electrodes. Small capacitive gap spacing can improve transduction efficiency and increase the total effective mass. The sidewall electrodes can reduce electrical noise in comparison to silicon structures in which sheet resistance is orders of magnitude higher.

In some implementations, batch wafer or panel-level processing methods can be used to eliminate or reduce die-level processing. Advantages of a batch process at a wafer, panel, or a sub-panel level include a large number of units fabricated in parallel in the batch process, thus reducing costs per unit as compared to individual die level processing. The use of batch processes such as lithography, etching, vapor deposition, and plating over a large substrate in some implementations allows tighter tolerances and reduces die-to-die variation.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

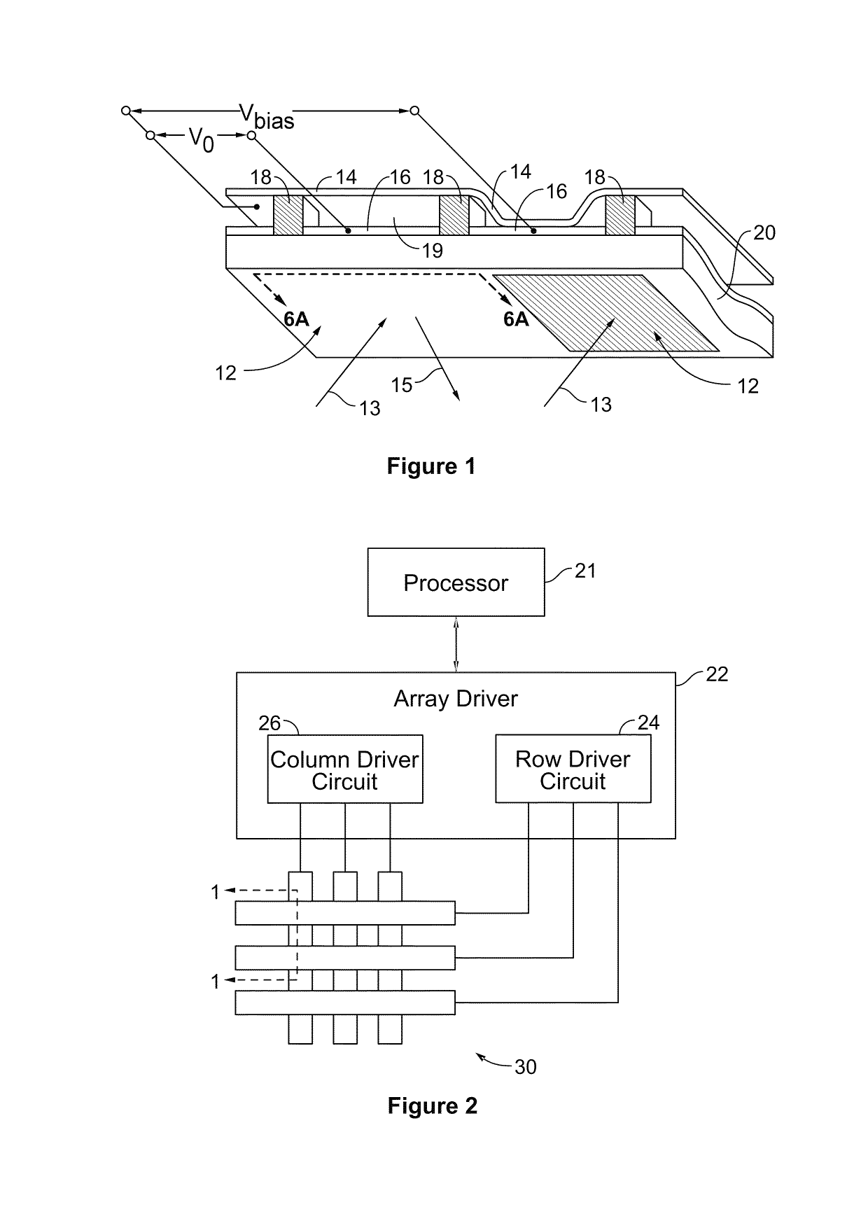

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

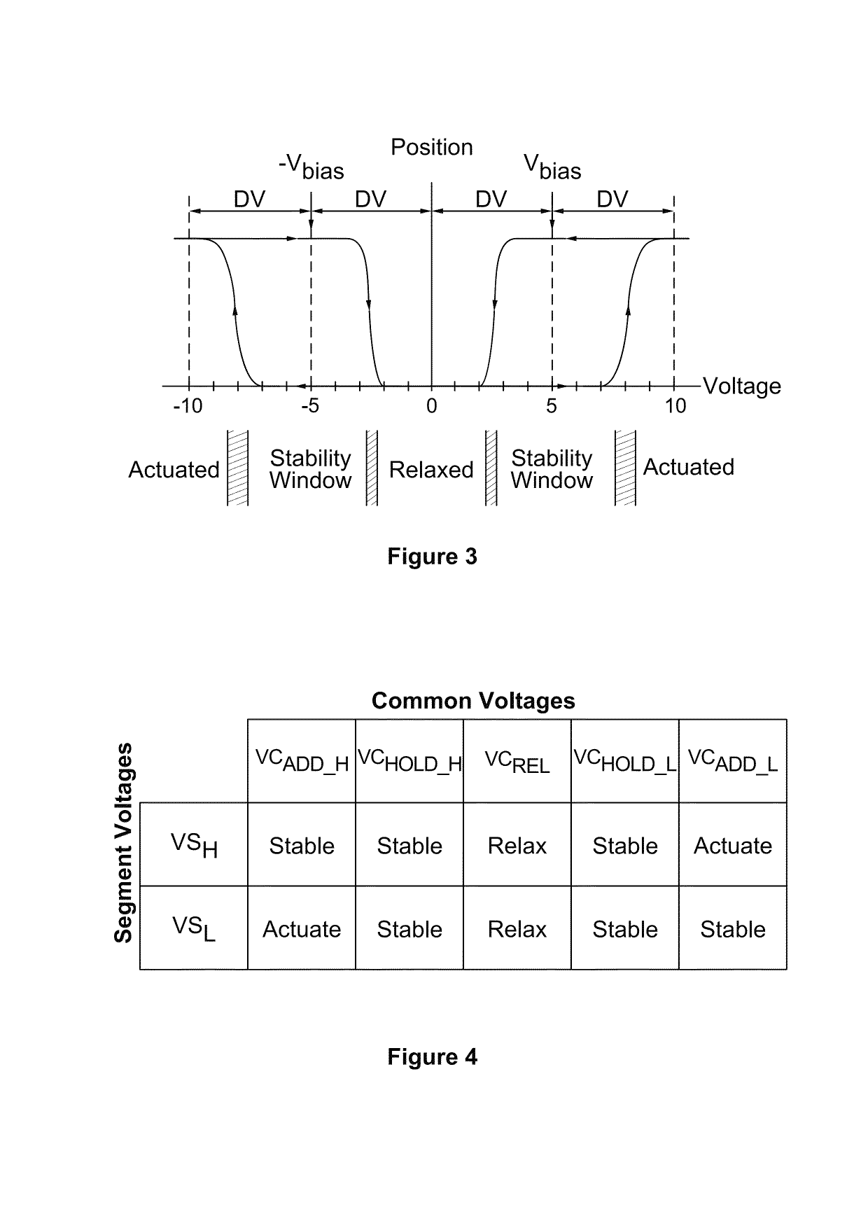

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

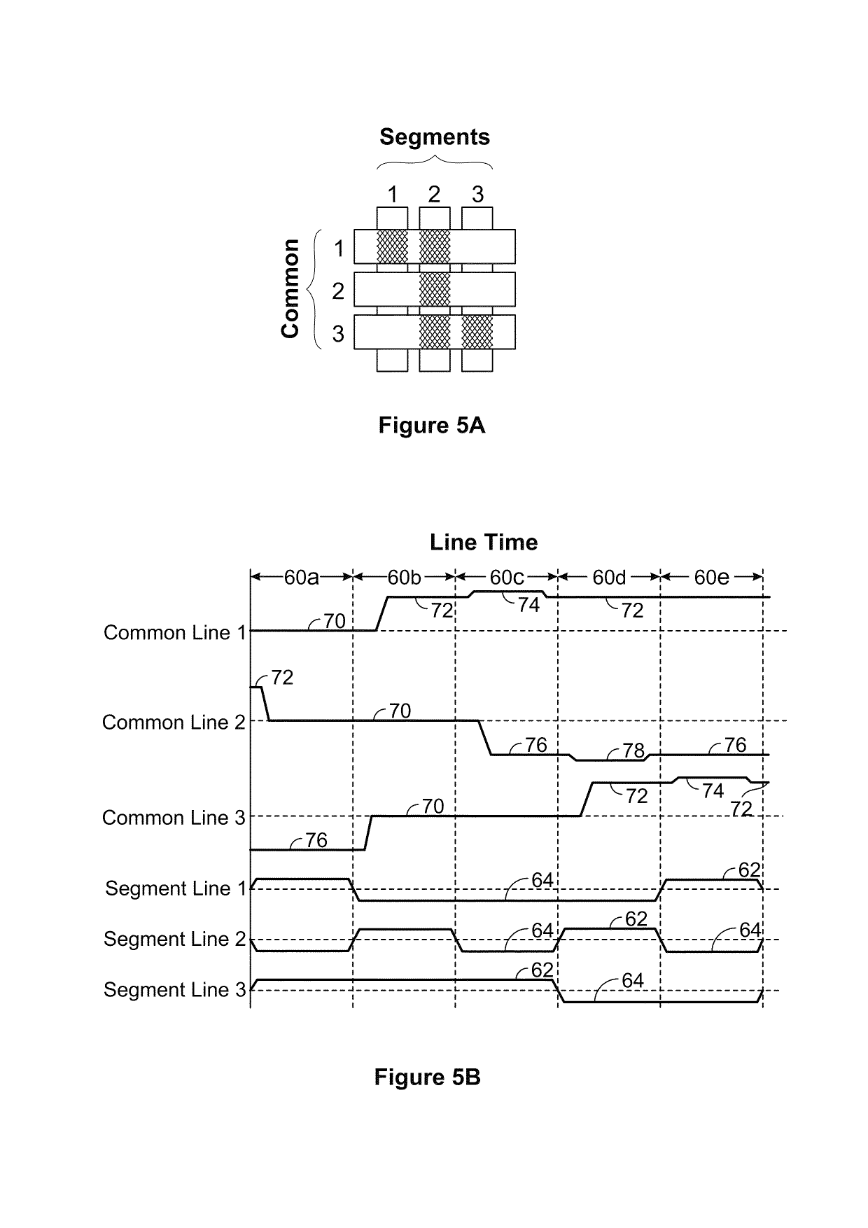

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}−relax and VC_{HOLD}_{_{—}}_{L}−stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

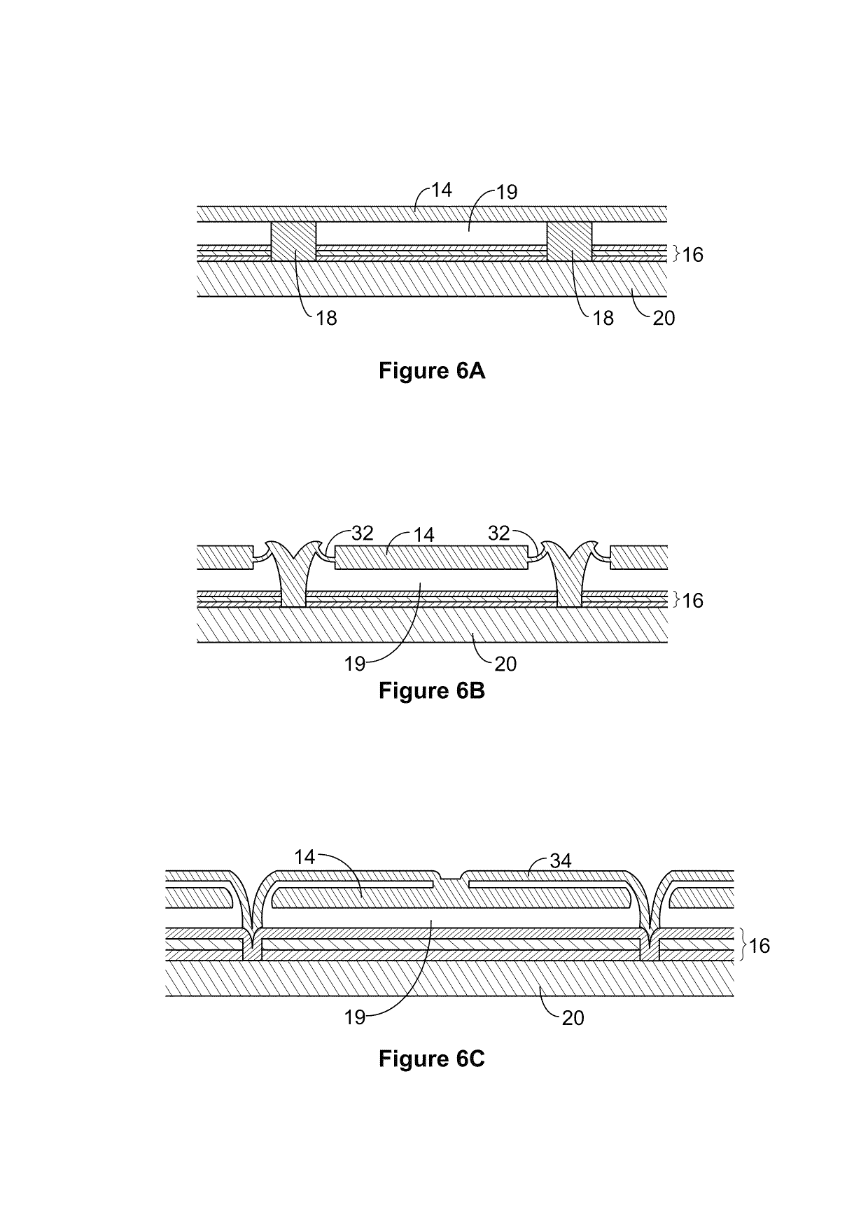

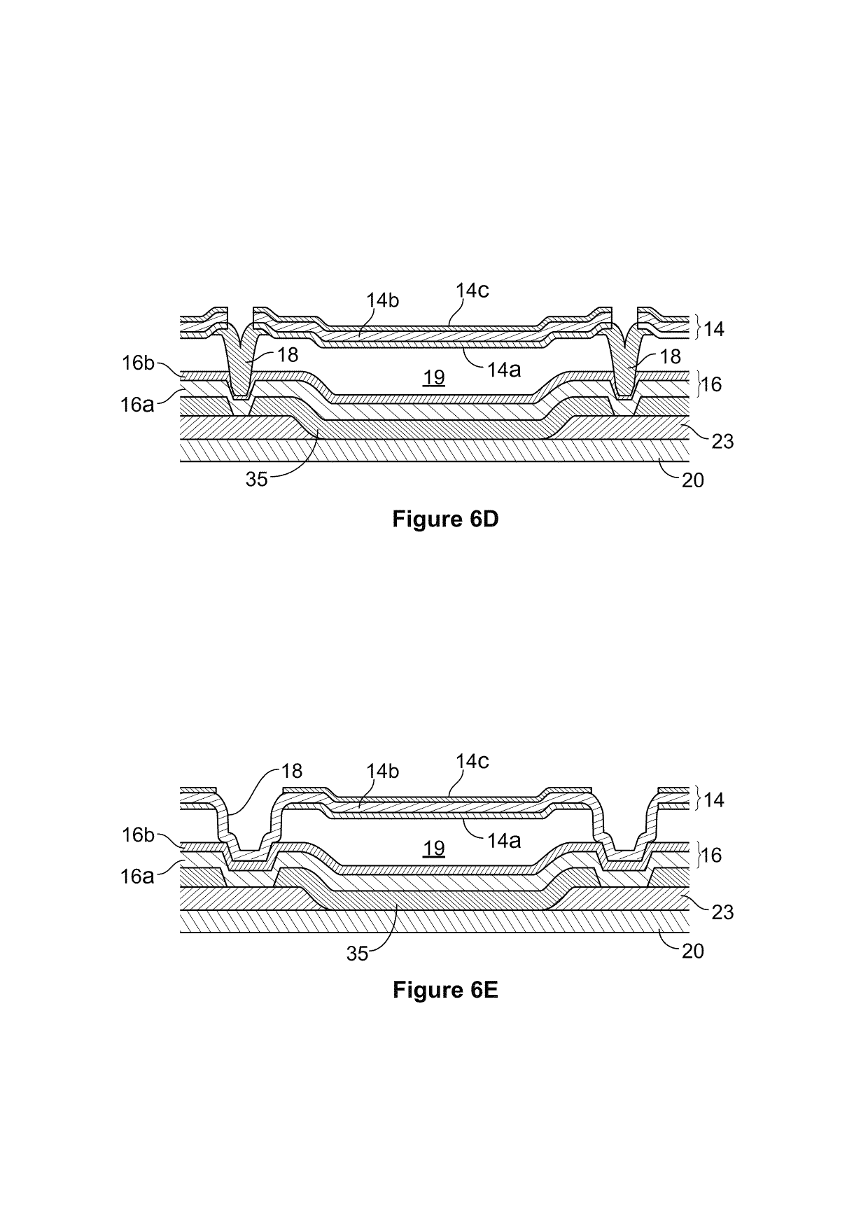

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

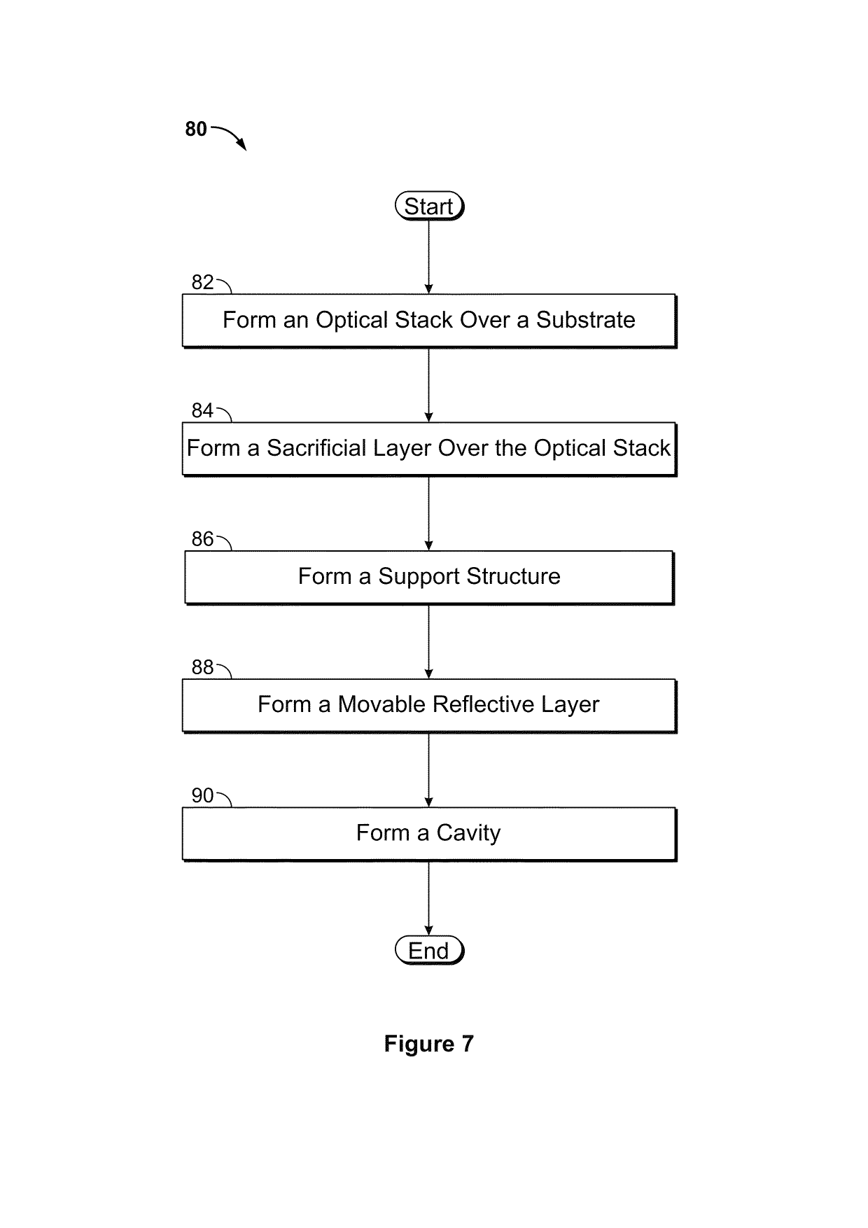

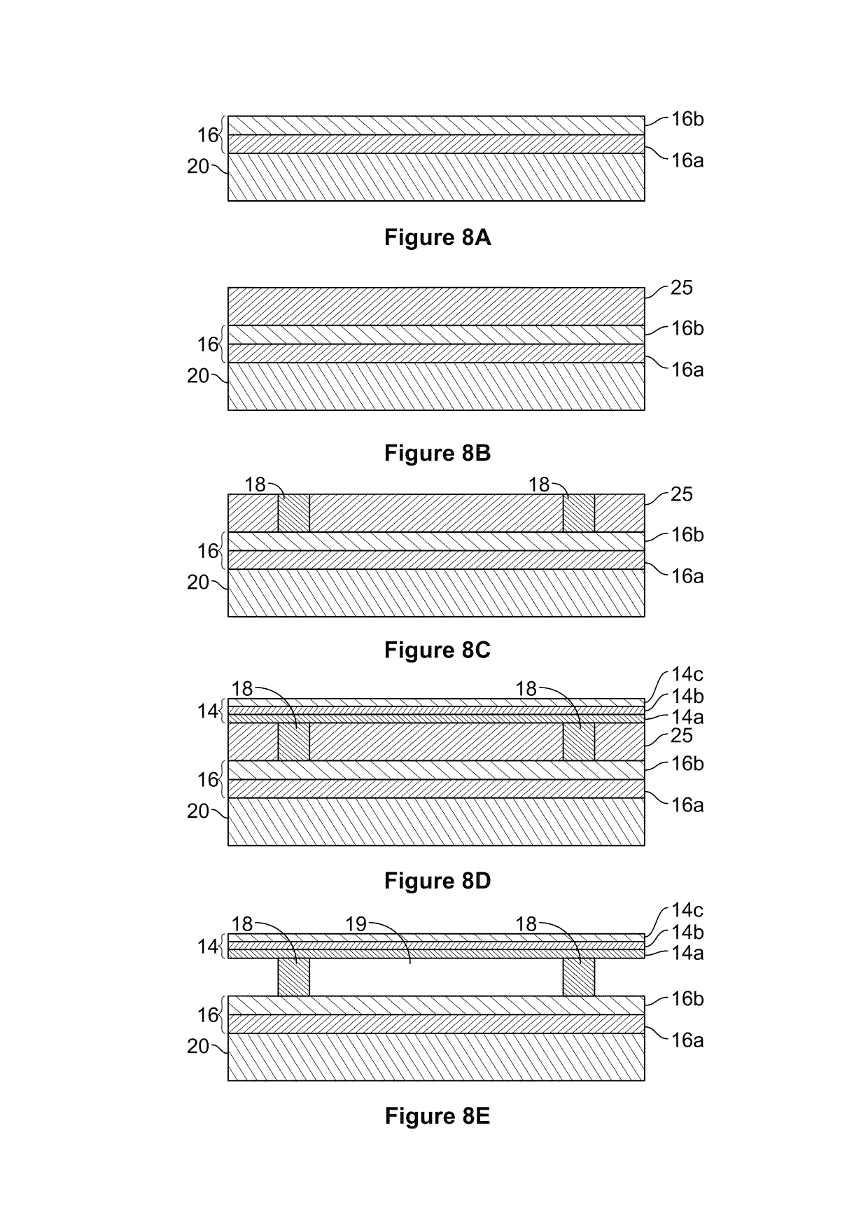

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

EMS devices also may be implemented in electrostatic structures including electrostatically transduced inertial sensors, resonators, and actuators. For example, inertial sensors include accelerometers, gyroscopes and other resonant sensors. In some implementations, one or more inertial sensors or other electrostatically transduced structures may be mounted, joined or otherwise connected to one or more EMS devices, such as an IMOD display device.

In some implementations, a glass EMS electrostatic structure includes a glass body having a support structure, one or more movable masses, coupling flexures, and one or more sidewall electrodes. In some implementations, the sidewall electrodes include one or more glass sidewall surfaces that extend through the thickness of the glass body and are wholly or partially coated with a conductive material. In some implementations, a glass EMS electrostatic structure includes one or more pairs of sidewall electrodes configured for capacitance sensing and/or actuation. The distance between the sidewall electrodes of a pair can be on the order of about 1 micron or larger. The glass body may have a thickness of up to about 1 mm or more, for example several hundred microns, such that the sidewall electrodes have high aspect ratios. EMS electrostatic structures include any electrostatically transduced EMS structures including sensors, oscillators, actuators and the like. The high aspect ratio of some implementations of the glass EMS electrostatic structures permits the structures to exhibit high transduction efficiency and high quality signals.

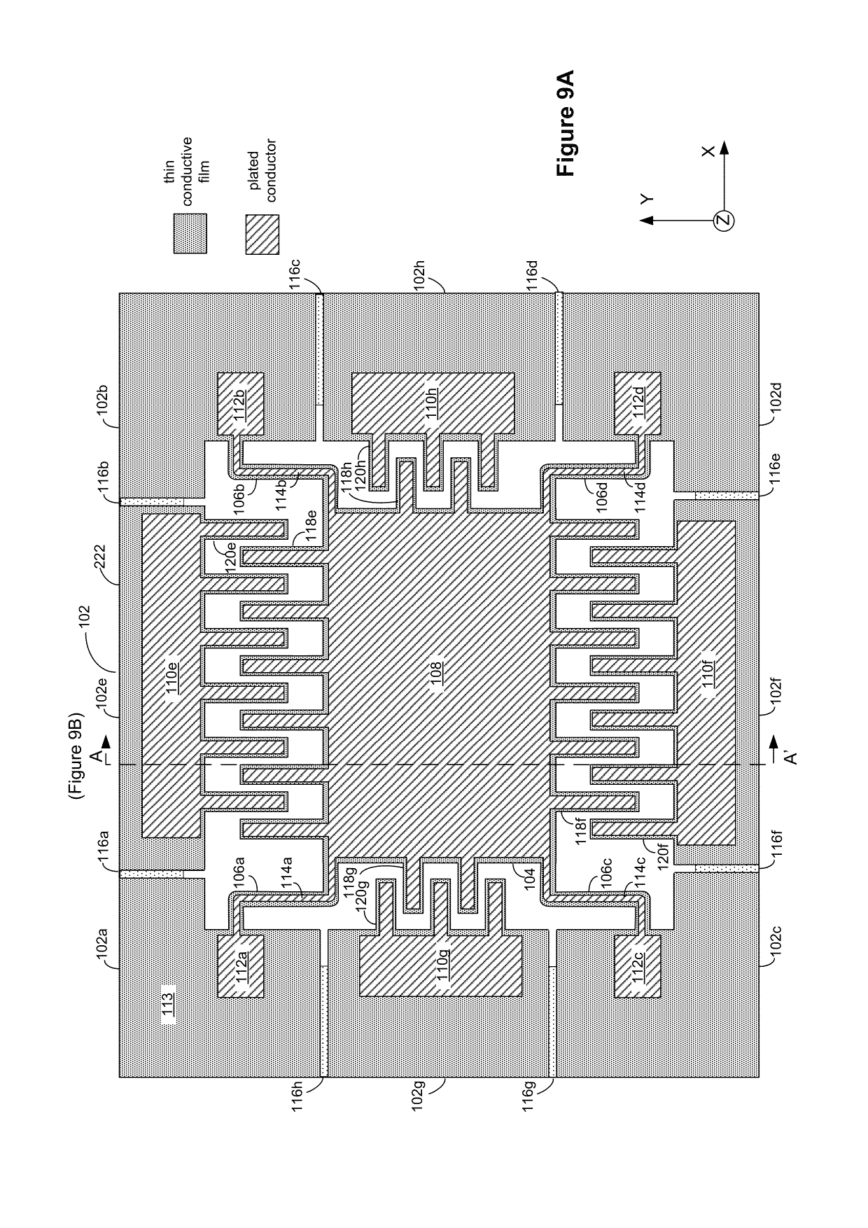

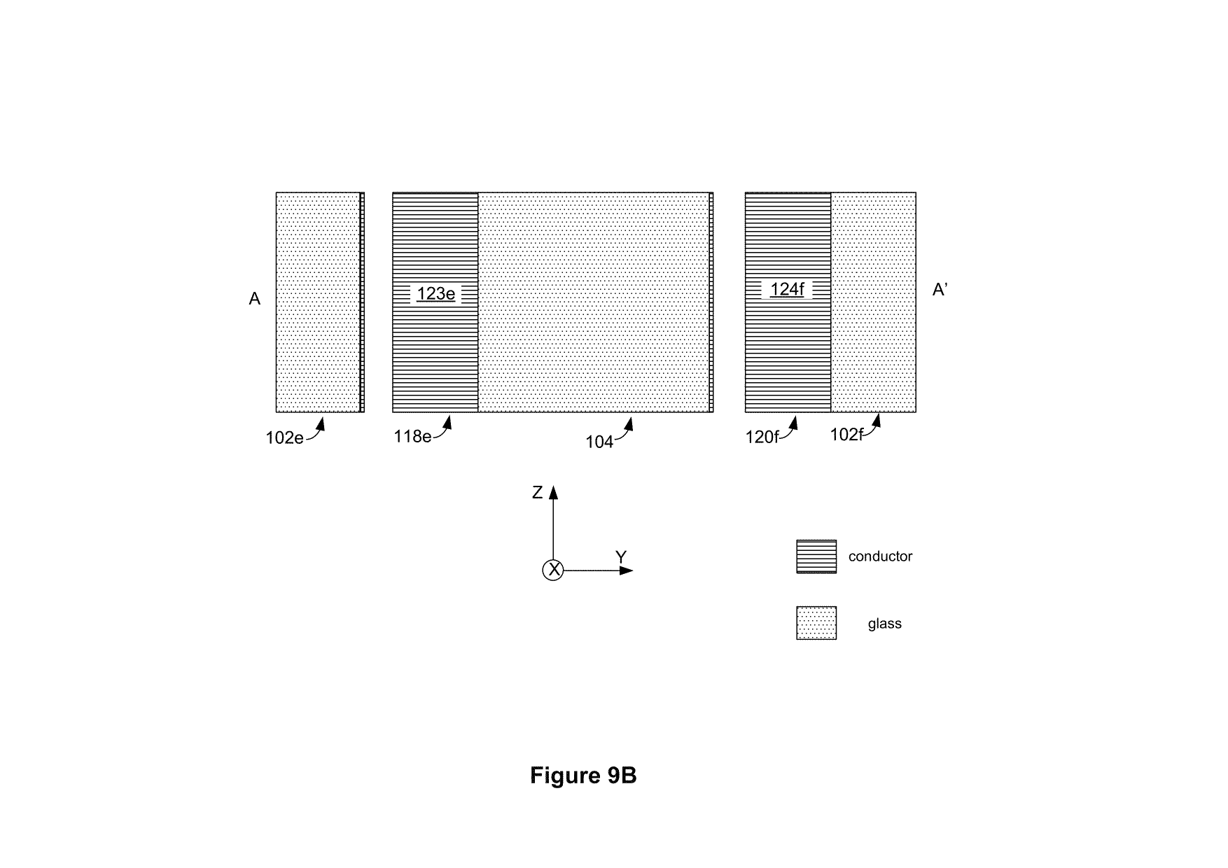

FIG. 9A shows an example of a schematic illustration of a top view of a glass EMS electrostatic structure. The glass electrostatic EMS structure includes a support structure 102 and a movable mass 104 formed from a glass body 222. The support structure 102 includes the peripheral region of the glass body 222 and is divided into electrically isolated, physically connected support structure segments 102a-102h. The support structure 102 is connected to the movable mass 104 by coupling flexures 106a-106d. The coupling flexures 106a-106d permit the movable mass 104 to move while the support structure 102 remains substantially stationary. In the example depicted in FIG. 9A, the top surfaces of the glass body 222, including the support structure segments 102a-102h, the coupling flexures 106a-106d, and the movable mass 104, are covered with a conductive thin film 113. A plated conductor is patterned over the conductive thin film 113 to define a top movable electrode 108, top stationary electrodes 110e-110h, contact pads 112a-112d, and conductive routing lines 114a-114d. The conductive routing lines 114a-114d provide conductive pathways between the top movable electrode 108 and the contact pads 112a-112d. In some implementations, for example, the contacts pads 112a-112d can be biased or grounded. In this manner, the top movable electrode 108 and the movable mass 104 can be biased or grounded according to various implementations.

Each of the support structure segments 102a-102h includes one of the top stationary electrodes 110e-110h or one of the contact pads 112a-112d, with the support structure segments 102a-102d including contact pads 112a-112d, respectively, and the support structure segments 102e-102h including the top stationary electrodes 110e-110h, respectively. The support structure segments 102a-102h, and their respective contact pads 112a-112d or top stationary electrodes 110e-110h, are electrically separated from one another by electrical isolation segments 116a-116h. In some implementations, the electrical isolation segments 116a-116h include uncoated trenches within the support structure 102.

Four sets of fingers 118e-118h extend from the movable mass 104, one set from each side of the movable mass 104, with four sets of fingers 120e-120h extending from the support structure 102, one set from each of the support structure segments 102e-102h. The glass EMS electrostatic structure includes four three-dimensional comb-type interdigitated electrode pairs. Specifically, the sidewall surfaces (not shown) of each of the eight sets of fingers 118e-118h and 120e-120h are conductive, forming a three-dimensional comb-type electrode structure, with the eight comb-type electrode structures forming four three-dimensional comb-type interdigitated electrode pairs. The fingers 118e and 120e form a three-dimensional interdigitated electrode pair, the fingers 118f and 120f form a three-dimensional interdigitated electrode pair, the fingers 118g and 120g form a three-dimensional interdigitated electrode pair, and the fingers 118h and 120h form a three-dimensional interdigitated electrode pair. The four comb-type electrode structures formed by the four sets of fingers 118e-118h are electrically connected to the top movable electrode 108. The four comb-type electrode structures formed by each of the four sets of fingers 120e-120h are each electrically connected to one of the top stationary electrodes 110e-110h and are electrically isolated from each other by the electrical isolation segments 116a-116h.

The movable mass 104 can be a proof mass, a vibratory mass, resonant mass or any other type of movable mass that can be employed in an EMS electrostatic structure. In some implementations, the movable mass 104 and the support structure 102 are capacitively coupled by the interdigitated electrode pairs formed by the fingers 118e-118h and 120e-120h such that movement of the movable mass 104 is detectable by a change in capacitance between the electrodes of one or more of the electrode pairs. For example, in some implementations, the movement of the movable mass 104 can result in a change in the distance between the electrodes of one or more electrode pairs, which can be measured by a resulting change in the capacitance between the electrodes of one or more electrode pairs.

In some implementations, the movable mass 104 and the support structure 102 are capacitively coupled by the interdigitated electrode pairs formed by the fingers 118e-118h and 120e-120h such that movement of the movable mass 104 can be induced by application of an electrostatic force to one or more of the electrode pairs. For example, in some implementations, application of a voltage difference across the electrodes of an electrode pair can result in a deflection of the movable mass 104 by electrostatic forces.

The top movable electrode 108 and thus the comb-type electrode structures formed by each set of fingers 118e-118h can be addressed by the contact pads 112a-112d. The comb-type electrode formed by each set of fingers 120e-120h can be addressed by the top stationary electrodes 110e-110h, respectively. In some implementations, the plated conductor of the top stationary electrodes 110e-110h extends to the edges and down the sidewall surfaces of the fingers 120e-120h, with the sidewall surfaces also plated.

The support structure 102, including the support structure segments 102a-102h, the movable mass 104, the coupling flexures 106a-106d, and the fingers 118e-118h and 120e-120h can be formed from a single glass body 222. In some implementations, the support structure 102, the movable mass 104, the coupling flexures 106a-106d, and the fingers 118e-118h and 120e-120h can extend through most or all of the thickness of the glass body 222. Although not depicted in FIG. 9A, various other components may be present within the glass body 222. For example, the support structure 102 may include one or more through-glass via interconnects and associated surface metallization such as conductive contact pads and conductive routing.

FIG. 9B shows an example of a cross-sectional schematic illustration of a glass EMS electrostatic structure including sidewall electrodes. In particular, FIG. 9B shows a cross-sectional schematic illustration of the glass EMS electrostatic structure along line A-A′ shown in FIG. 9A. As noted above, in some implementations, the sidewall surfaces of each of the eight sets of fingers 118e-118h and 120e-120h are coated with a conductive material to form sidewall electrodes. Line A-A′ in FIG. 9A includes the conductive coating on the sidewall surfaces of the fingers 118e and 120f through which line A-A′ extends. In the example depicted in FIG. 9B, the support structure segments 102e and 102f and the movable mass 104 are glass, with sidewall surfaces of fingers 118e and 120f coated with a conductive material to form sidewall electrodes 123e and 124f. In the example depicted, the entire thickness of the sidewall surfaces of the fingers 118e and 120f is coated with a conductive material. In some other implementations, a coating may extend over most of the thickness, with for example, ten percent or less of the bottom thickness left uncoated. The conductive material can be, for example, a conductive thin film and/or a plated conductor. Examples of conductive materials include palladium (Pd), nickel (Ni), ruthenium (Ru), silver (Ag), cobalt (Co), platinum (Pt), titanium (Ti), gold (Au), silicon germanium (SiGe), ITO and other transparent conducting oxides, Mo, Cu, Al, as well as alloys and combinations thereof.

In some implementations, the glass body can be a photochemically etched glass substrate. Photochemically etchable glasses include silicon oxide/lithium oxide (SiO₂/Li₂O)-based glasses doped with one or more noble metals such as Ag and cerium (Ce). Treating the photochemically etchable glass with electromagnetic radiation and heat can result in chemical reactions that render the glass etchable with etchants such as hydrofluoric (HF) acid. Examples of photochemically etchable glasses include APEX™ glass photo-definable glass wafers by Life BioScience, Inc. and Forturan™ photo-sensitive glass by Schott Glass Corporation. The length and width (the X and Y dimensions, respectively, in the examples of FIGS. 9A and 9B) of the glass body can range from tens of microns to a few millimeters. The thickness of the glass (the Z dimension in the examples of FIGS. 9A and 9B) can range from 50 microns to 1 mm, for example, from about 100 to 500 microns.

In some implementations, the glass EMS electrostatic structure can have at least one sidewall electrode, and in some implementations, at least one pair of capacitive sidewall electrodes. Capacitive sidewall electrodes can be implemented in any appropriate configuration, such as comb-type electrode structures and parallel plate structures. The capacitive gap between the sidewall electrodes of a pair of sidewall electrodes can be as small as about 1 or 2 microns. The sidewall electrodes of the electrostatic structure may be precisely defined, having substantially vertically straight sidewalls and substantially uniform thickness. The aspect ratio of a glass electrostatic EMS structure can be characterized in terms of the height of sidewall electrodes and the capacitive gap between adjacent sidewall electrodes. For example, the aspect ratio of the glass electrostatic EMS structure shown in FIGS. 9A and 9B can be characterized as the height of the sidewall electrodes divided by the width between adjacent fingers. The height of the sidewall electrodes is determined by the thickness of the glass body as described above with respect to FIG. 9B. The width between adjacent fingers can be reduced by increasing the thickness of the conductive material that coats the surface of sidewall electrode supports. Aspect ratios can range from about 20:1 to 100:1 or higher. The resulting high aspect ratios can provide high electrostatic transduction efficiency.

The coupling flexures tether the movable mass or masses to the support structure, and also can determine the frequency response of the glass electrostatic structure as well as the mode of mechanical vibration. They also may be precisely defined, having substantially straight sidewalls and uniform width throughout the thickness of the glass body. The length of the coupling flexures can be at least about 50 microns. The width of the coupling flexures can range, for example, from about 2 to 10 microns, though this can vary depending on the thickness of the glass body. In the example of FIG. 9A, the coupling flexures 106a-106d are S-shaped. In some other implementations, they may be any appropriate shape including U-shaped or serpentine-shaped. For example, a serpentine-shaped flexure can have any number of turns to adjust the stiffness of the flexure. In some implementations, a glass EMS electrostatic structure can include coupling flexures that tether a plurality of coupled movable masses to each other.

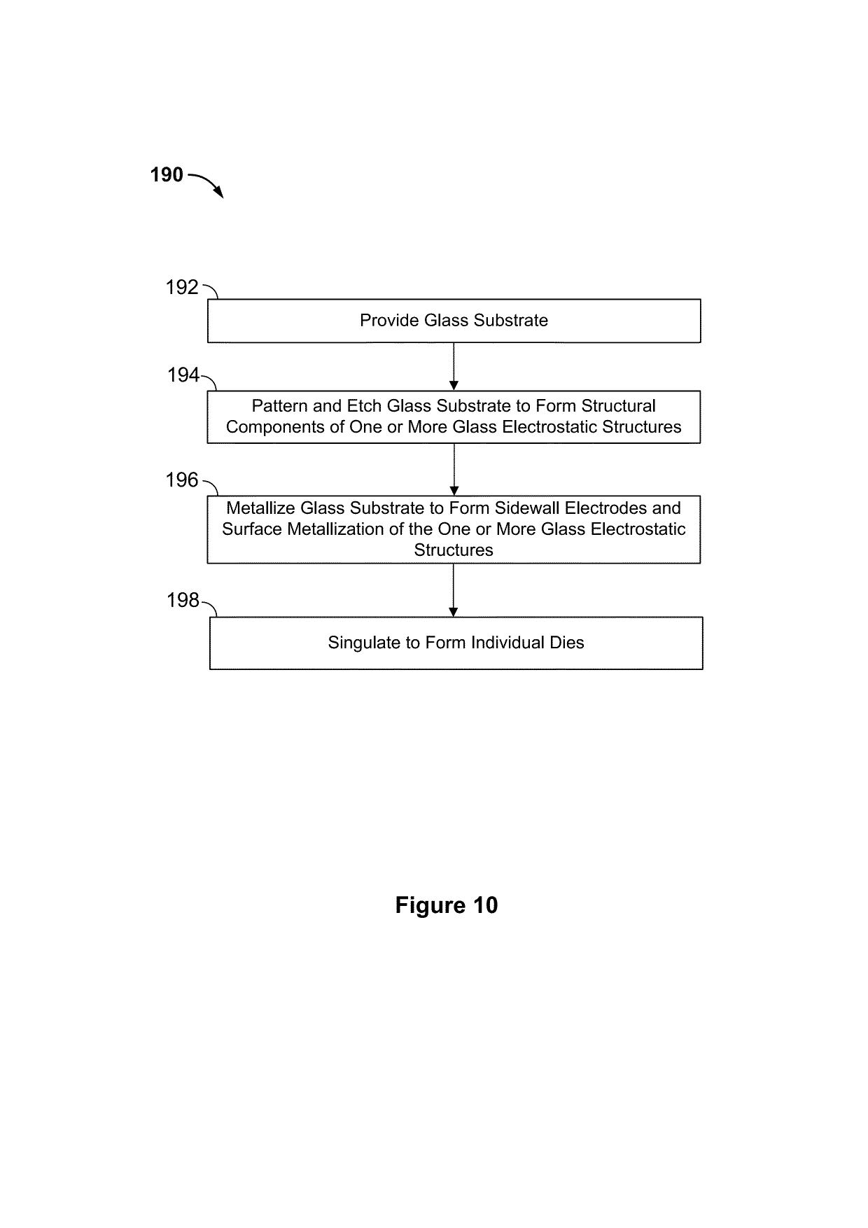

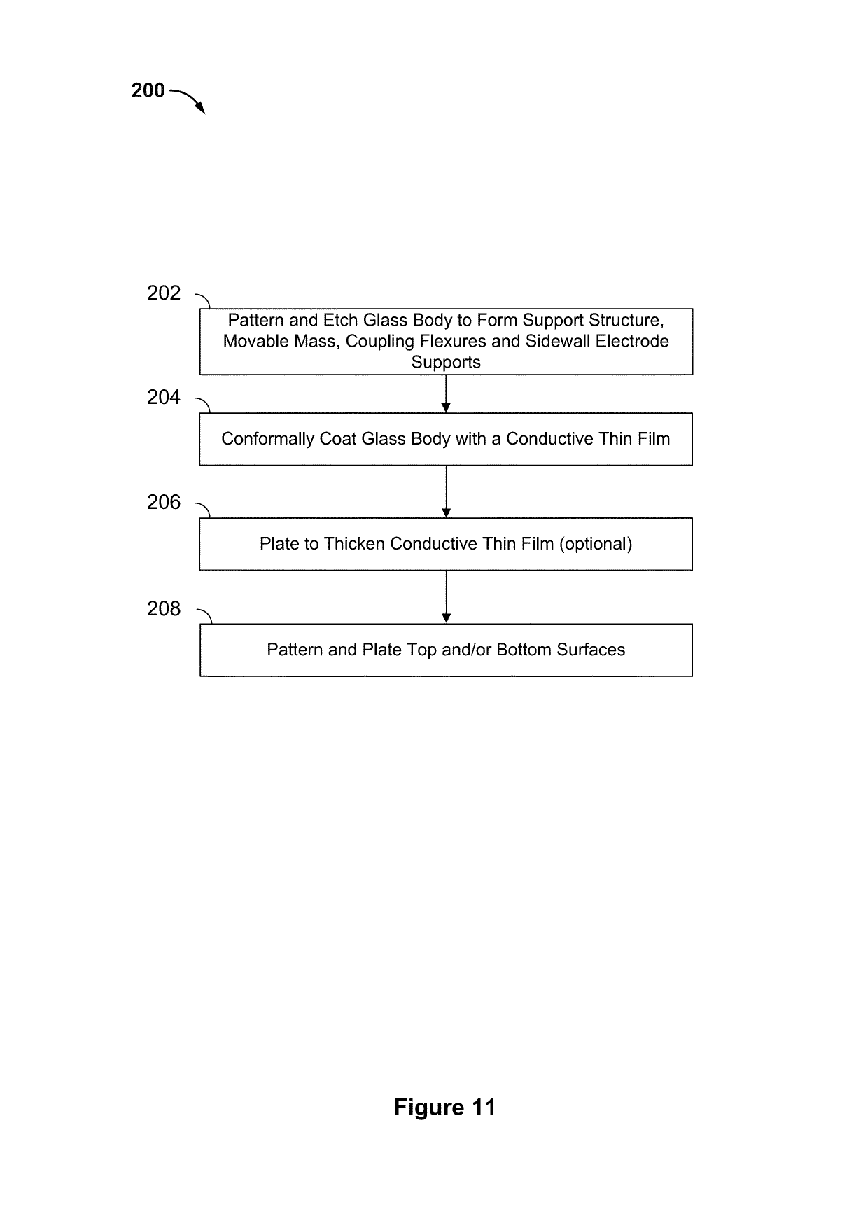

FIGS. 10 and 11 show examples of flow diagrams illustrating manufacturing processes for glass EMS electrostatic structures. First, turning to FIG. 10, at block 192 of the process 190, a glass substrate is provided. The glass substrate can be a photochemically etchable glass as described above. In some implementations, the glass substrate can be a glass panel, wafer, or other large glass substrate that can be singulated into individual dies after processing to form multiple glass EMS electrostatic structures. Glass panels can include sub-panels cut from larger glass substrates. For example, in some implementations, a glass substrate can be a square or rectangular sub-panel cut from a larger panel of glass. In some implementations, a glass substrate can glass plate having an area on the order of four square meters. In some implementations, a glass substrate can be a round substrate with a diameter of 100 millimeters, 150 millimeters, or other appropriate diameter.

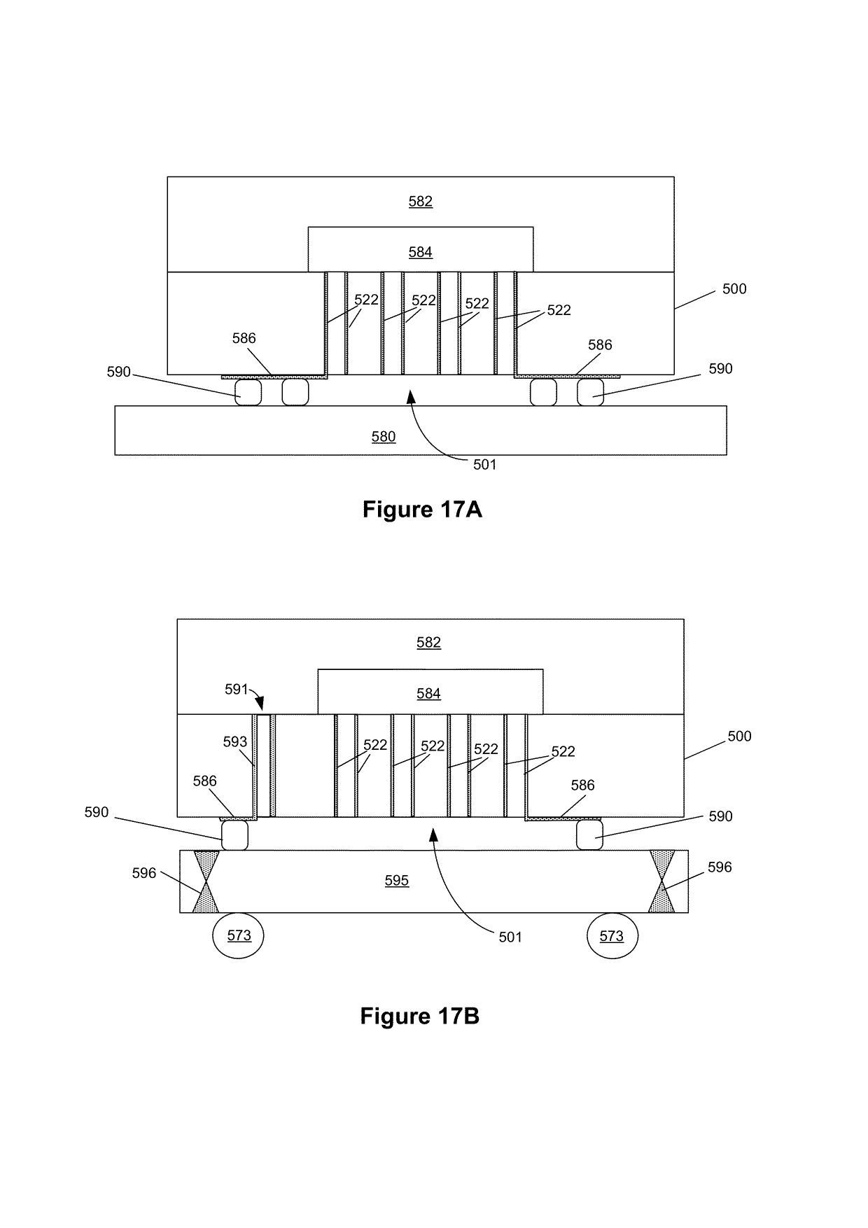

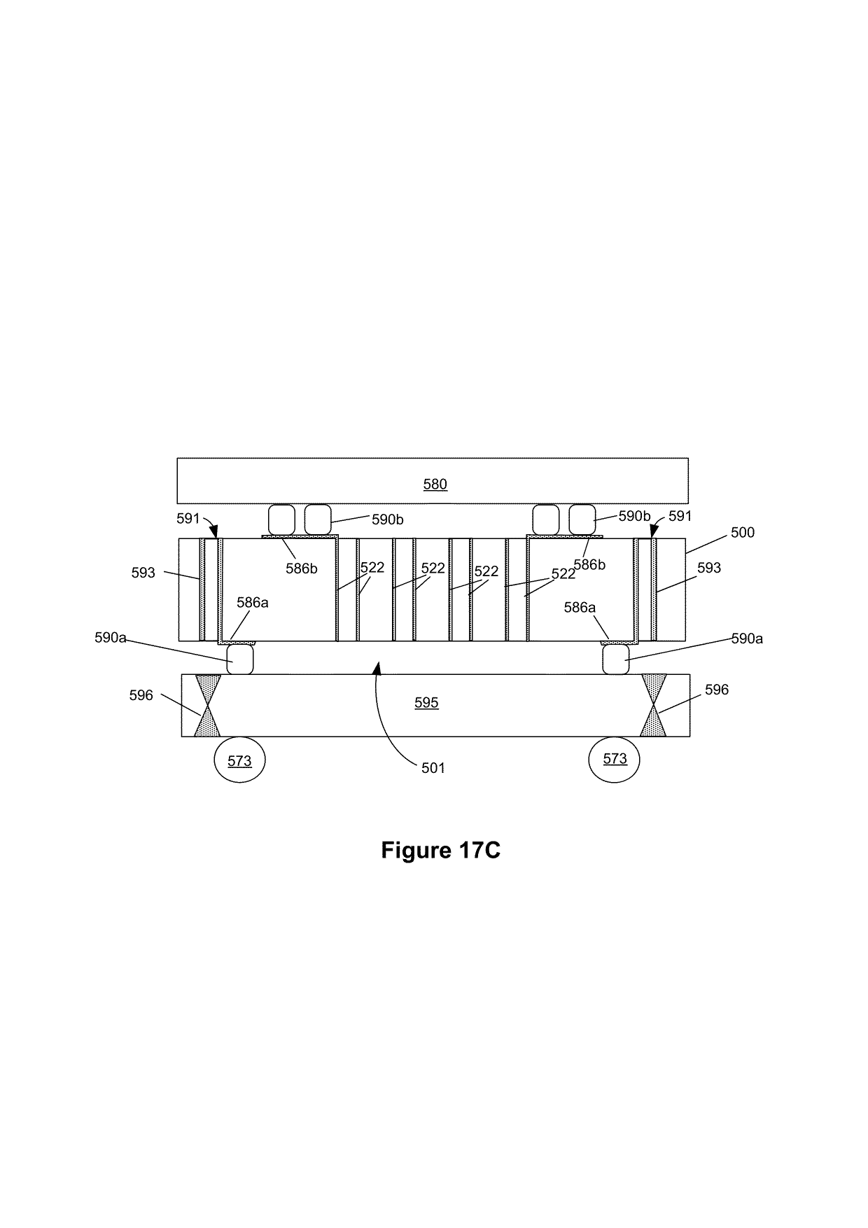

The process 192 continues at block 194, with patterning and etching the glass substrate. As described further below, in some implementations, the glass substrate can be patterned and etched to form the structural components of one or more glass electrostatic structures to be formed from the glass substrate. The structural components can include support structures, movable masses, coupling flexures and sidewall electrode supports. Etching the glass substrate involves etching through the entire thickness of the glass substrate to form these or other structural components. In some implementations, etching the glass substrate can include etching one or more additional features such as through-glass vias. Further details of patterning and etching a glass substrate according to various implementations are given below. The process 190 continues at block 196 with metallization of the glass substrate to form sidewall electrodes and surface metallization. Surface metallization can include electrodes, contact pads, bond rings, and conductive routing on the top and/or bottom surface of the glass substrate. Block 196 can involve a conformal process to coat etched sidewalls of the glass substrate to form sidewall electrodes. Examples of conformal deposition processes include atomic layer deposition (ALD), CVD, and electroless plating. In some implementations, one or more additional plating processes to thicken the sidewall electrodes and/or form top surface electrodes or other surface metallization can be used. In some implementations, block 196 can include metallizing the sidewalls of one or more through-glass via holes to form through-glass via interconnects. It should be noted that block 196 can include one or more operations that are performed prior to one or more operations of block 194. For example, in some implementations, top surface electrodes can be formed prior to etching the glass substrate. Examples of various process sequences are described below with respect to FIGS. 11-15G. The process 190 can continue with an optional operation of singulating the glass substrate to form individual dies at block 198. Each die can include a glass EMS electrostatic device. The individual glass EMS electrostatic devices can then be further packaged, for example, with an integrated circuit (IC) device. Examples of packaging glass EMS electrostatic devices are described below with respect to FIGS. 17A-17C.

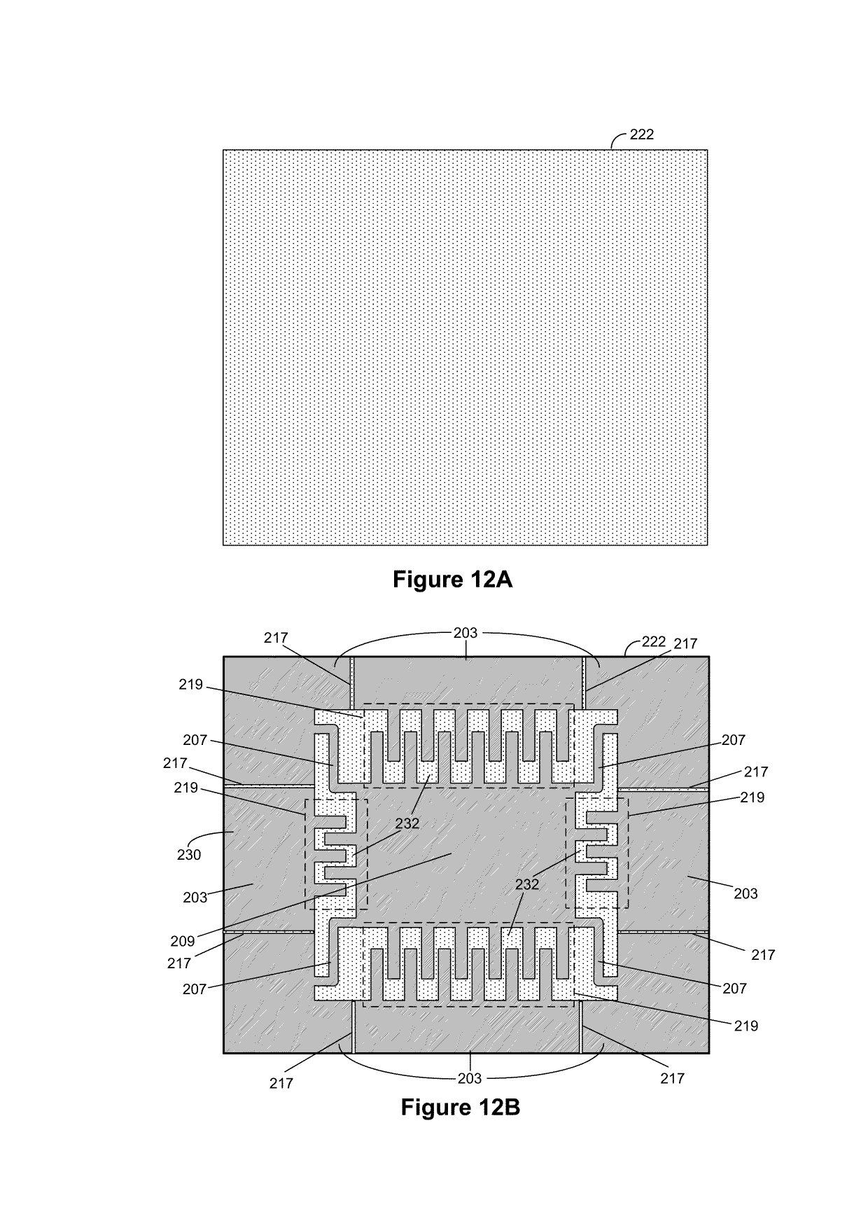

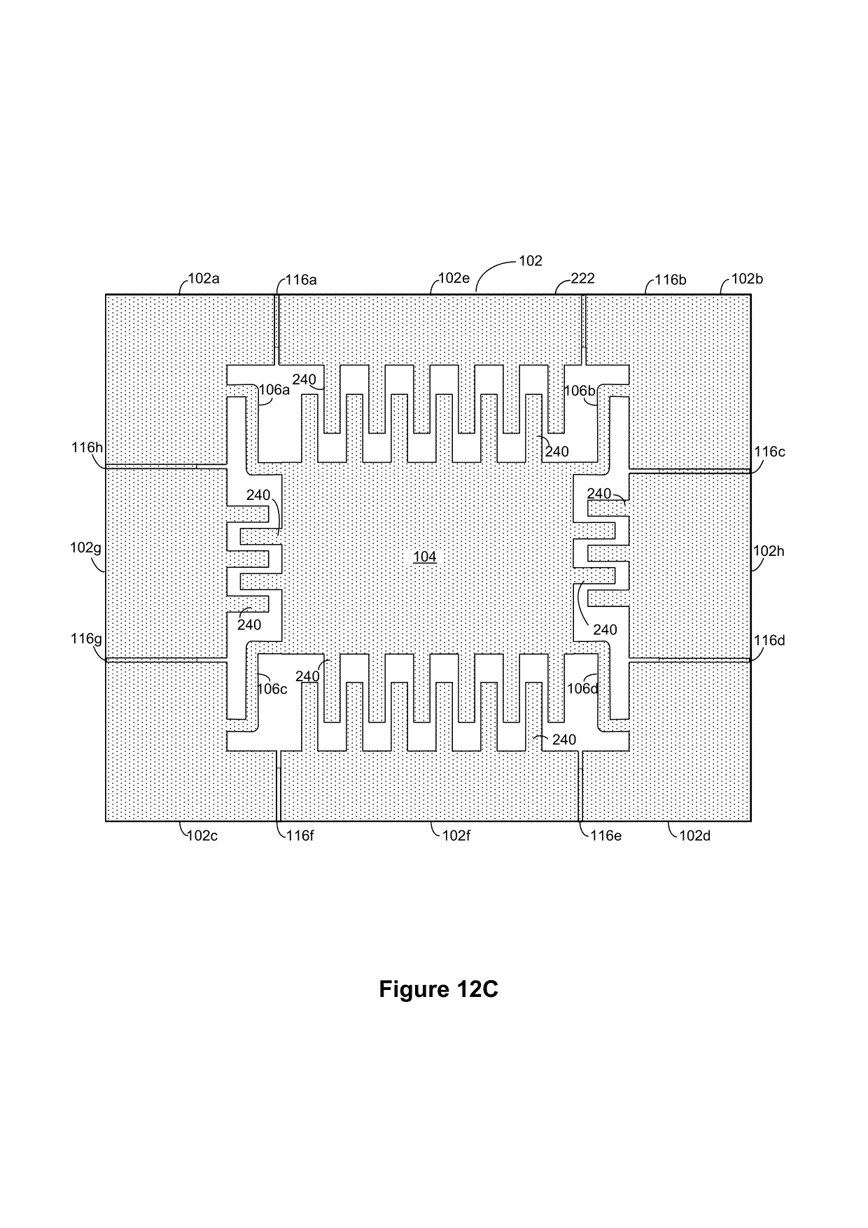

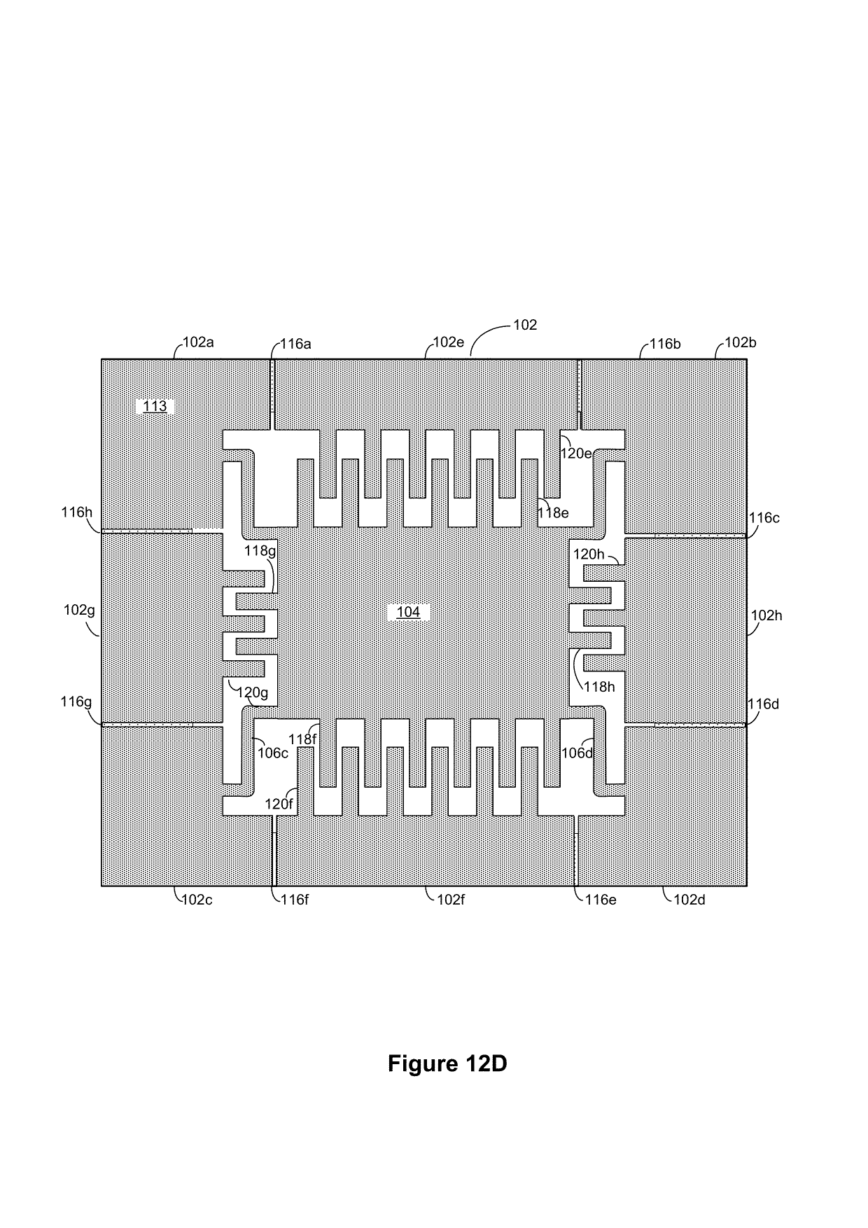

FIG. 11 shows an example of a flow diagram illustrating a manufacturing process for a glass EMS electrostatic structure that involves patterning and etching a glass body prior to metallization. FIGS. 12A-12D show examples of schematic illustrations of various stages in a method of making a glass EMS electrostatic structure. In particular, FIGS. 12A-12D show examples of schematic illustrations of various stages in a method of making a glass EMS electrostatic structure shown in the example of FIG. 9A. While FIG. 11 describes a manufacturing process for, and FIGS. 12A-12D show examples of, a single glass EMS electrostatic structure, in some implementations, the manufacturing process is performed as a batch process at a wafer or panel level, with various processing operations performed on a single glass wafer or panel for multiple glass electrostatic structures as described above with reference to FIG. 10.

Turning to FIG. 11, at block 202 of the process 200, a glass body is patterned and etched to form a support structure, a movable mass, coupling flexures and sidewall electrode supports. The glass body can be a photochemically etchable glass as described above. Patterning the glass body can include masking the glass body to define the support structure, movable mass, coupling flexures and electrode supports and exposing the unmasked portions of the glass body to ultraviolet (UV) light and thermal annealing. Examples of mask materials can include quartz-chromium. The UV exposure can change the chemical composition of the unmasked portions such that they have higher etch selectivity to certain etchants. For example, in some implementations, a masked glass body is exposed to UV light having a wavelength between 280 and 330 nanometers. Exposure to UV light in this range can cause photo-oxidation of Ce³⁺ ions to Ce⁴⁺ ions, freeing electrons. Ag⁺ ions can capture these free electrons, forming Ag atoms. In some implementations, a two-stage post-UV exposure thermal anneal can be performed. In the first stage, Ag atoms can agglomerate to form Ag nanoclusters. In the second stage, crystalline lithium silicate (LiₛSiO₃) forms around the Ag nanoclusters. The masked regions of the glass body are chemically unchanged and remain amorphous. Thermal anneal temperatures can range from about 500° C. to about 600° C., with the second stage performed at a higher temperature than the first stage. In some implementations, the glass body is then exposed to an etchant, such as HF acid, which etches the crystalline portions of the glass body while leaving the vitreous amorphous portions substantially unetched. The etchant exposure time is long enough such that the glass body is etched through its thickness, forming the support structure, movable mass, coupling flexures and electrode supports. In some implementations, the etch is followed by a post-etch bake.

The above-described process is one example of patterning and etching a glass body, with other processes possible. In some implementations, for example, the glass body may include Al, Cu, Au, boron (B), potassium (K), sodium (Na), zinc (Zn), calcium (Ca), antimonium (Sb), arsenic (As), magnesium (Mg), barium (Ba), lead (Pb), or other additives in addition to or instead of the above-described components. In some implementations, the glass body may include various additives to modify melting point, increase chemical resistance, lower thermal expansion, modify elasticity, modify refractive index or other optical properties, or otherwise modify the characteristics of the glass body and/or glass electrostatic structure. For example, potassium oxide (K₂O) and/or sodium oxide (Na₂O) may be used to lower the melting point and/or increase chemical resistance of the glass body and zinc oxide (ZnO) or calcium oxide (CaO) may be used to improve chemical resistance or reduce thermal expansion. In some implementations, one or more other electron donors may be used in addition to or instead of Ce. In some implementations, the glass body may include one or more oxygen donors.

Example UV dosages can range from 0.1 J/cm² to over 50 J/cm². The UV wavelength and dosage can vary according to the composition and size of the glass body. The UV-induced chemical reactions can also vary depending on the chemical composition of the glass body, as can the subsequent thermal-induced reactions. Moreover, in some implementations, these reactions may be driven by energy sources other than UV radiation and thermal energy, including but not limited to other types of electromagnetic radiation. In general, treating the unmasked areas of the unetched glass body with one or more types of energy produces a crystalline composition such as polycrystalline ceramic.

Any etch process having a substantially higher etch selectivity for the crystalline portions of glass body than the amorphous portions of the glass body can be used, including wet and dry etching. In one example, 10% HF solution is employed for wet etching. In another example a fluorine-based dry etch is employed, using a chemistry such as a XeF₂, tetrafluoromethane (CF₄) or sulfur hexafluoride (SF₆). In some implementations, a dry etch process can include intermediate polymer backfill operations to passivate the etched sidewalls and facilitate formation of vertically straight sidewalls.

Depending on the etchant and the composition of the glass body, the etch selectivities can be at least 20:1, and in some implementations, 50:1 or higher. The corresponding achievable aspect ratios can be at least about 20:1, and in some implementations, about 50:1 or higher. The minimum allowable pitch (line plus space) of an interdigitated comb electrode structure and the minimum allowable gap between adjacent sidewall electrode supports after etching can depend on the thickness of the glass body as well as its composition and the particular etch process used. For example, for a 500 micron thick glass body, a pitch of 20 microns can be obtainable, with even smaller pitches obtainable for thinner glass bodies. In some implementations, a gap between adjacent sidewall electrode supports can be between about 2 and 50 microns. As described further below, the capacitive gap between adjacent sidewall electrodes can be narrowed further by metallization.

FIG. 12A is an example of a schematic illustration of a top view of an unetched glass body prior to masking. The glass body 222 can be a photochemically etchable glass substrate as described above, having lateral dimensions ranging from the tens of microns to a few millimeters and a thickness (not shown) ranging from about 50 microns to 1 mm. As indicated above, in some implementations, wafer or panel-level processing is performed; in such implementations, the unetched glass body 222 may be one repeating unit of a larger glass substrate or panel (not shown). FIG. 12B is an example of a schematic illustration of the glass body 222 shown in FIG. 12A after masking. A mask 230 overlies the glass body 222, covering portions of it to define a support structure, a movable mass, coupling flexures and electrode supports. In the example of FIG. 12A, the mask 230 includes the following regions: support structure defining regions 203, a movable mass defining region 209, coupling flexure defining regions 207, and sidewall electrode support defining regions 219. The support structure defining regions 203 of the mask 230 overlie the regions of the glass body 222 that will form support structure segments, such as the support structure segments 102a-102h shown in the example of FIG. 9A. The movable mass defining region 209 of the mask 230 overlies the region of the glass body 222 that will form a movable mass, such as the movable mass 108 shown in the example of FIG. 9A. The coupling flexure defining regions 207 of the mask 203 overlie the regions of the glass body 222 that will form coupling flexures, such as the coupling flexures 106a-106d shown in the example of FIG. 9A. The electrode support defining regions 219 of the mask 230 overlie regions of the glass body 222 that will form supports for sidewall electrode structures such as the fingers 118e-118h and 120e-120h shown in the example of FIG. 9A.

The glass body 222 includes four exposed regions 232, each of which is a contiguous region that defines the spacing between the sidewall electrode supports, spacing between the movable mass and the support structure, spacing between the coupling flexures and the support structure, and spacing between the coupling flexures and the movable mass. The exposed regions 232 are unmasked regions that will be etched through the thickness of the glass body 222. The glass body 222 also includes exposed isolation regions 217. The exposed isolation regions 217 are regions that correspond to electrical isolation segments, such as the electrical isolation segments 116a-116h shown in the example of FIG. 9A. In some implementations, etching is controlled such that the exposed regions 217 are etched only partially through the thickness of the glass body 222, forming trenches in the glass body 222 that separate support structure segments. Etching can be controlled in some implementations by limiting the width of the exposed isolation regions 217 to limit the diffusion of etchant into the glass body 222 in those regions. For example, in some implementations, the width of the exposed isolation regions 217 is no more than about 5 microns for a 500 micron thick glass body 222. In some implementations, the exposed isolation regions 217 have a width that is smaller than the smallest dimension of the exposed regions 232, such that the diffusion and etch rate through the exposed isolation regions 217 is lower than that through the exposed regions 232.

While FIG. 12B shows an example of a mask 230 on a single side of the glass body 222, in some implementations, both top and bottom sides of the glass body 222 can be masked. For example, in some implementations, a bottom side mask can include exposed isolation regions aligned with the exposed isolation regions 217, such that corresponding trenches are formed in the bottom side of the glass body 222.

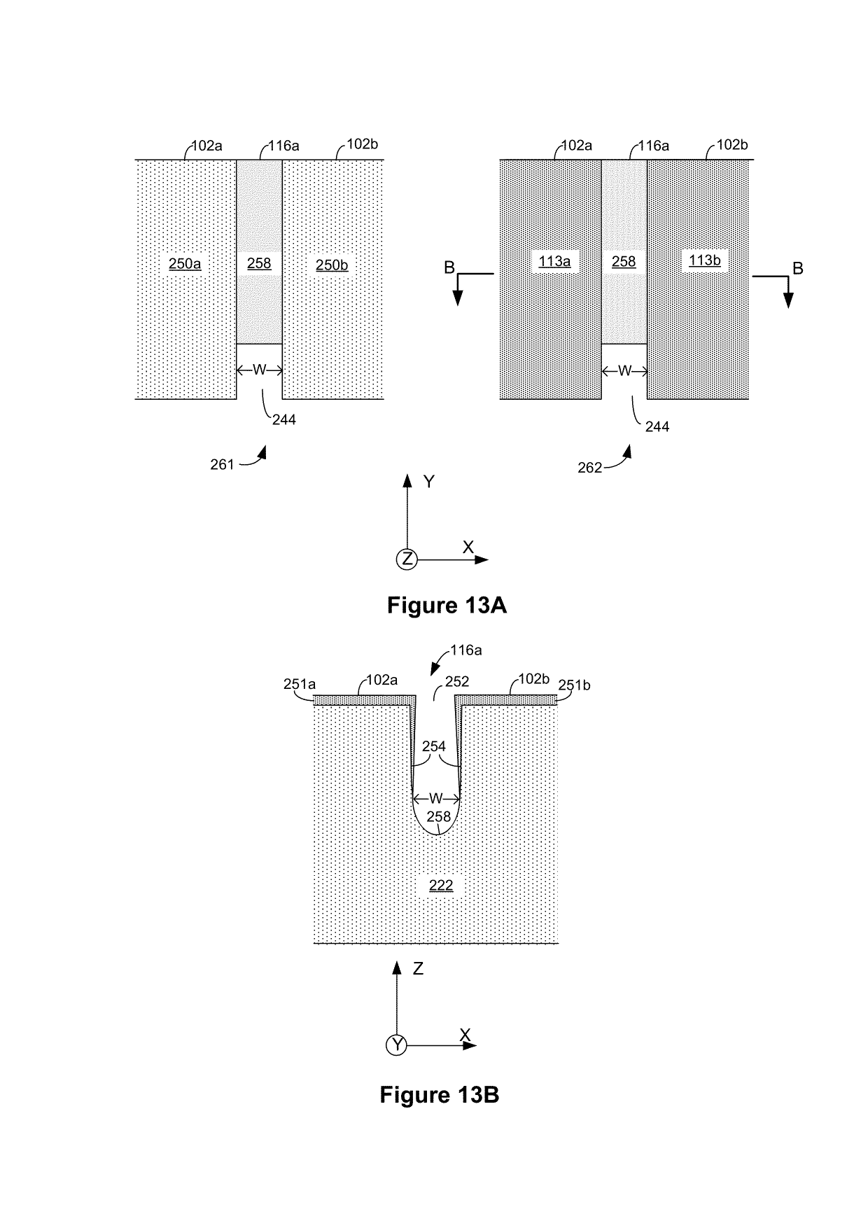

FIG. 12C is an example of a schematic illustration of the glass body shown in FIGS. 12A and 12B after crystallization and selective etching of its exposed regions. The glass body 222 in the example of FIG. 12C includes the support structure 102 including the support structure segments 102a-102h, the movable mass 104, the coupling flexures 106a-106d, the electrical isolation segments 116a-116h, and sidewall electrode support structures 240. The sidewall electrode support structures 240 have substantially vertically straight sidewalls (not shown) that extend through the thickness of the glass body 222. In the example of FIG. 12C, the sidewall electrode support structures 240 are arranged as interdigitated pairs. The electrical isolation segments 116a-116h are trenches extending partially through the glass body 222, as described further below with respect to FIGS. 13A and 13B.

Returning to FIG. 11, the process 200 continues at block 204 with conformally coating the glass body with a conductive thin film. Block 204 can involve any conformal deposition process, such as PVD, CVD, ALD, evaporation, and electroless plating. In some implementations, block 204 involves ALD or electroless plating. Examples of conductive materials that can be deposited, plated or otherwise formed in block 204 include Pd, Ni, Ru, Ag, Co, Pt, Ti, Au, ITO and other transparent conducting oxides, Mo, Cu, and Al, as well as alloys and combinations thereof.

In some implementations, the conductive thin film can be a bilayer including an adhesion layer and an outer layer. The adhesion layer promotes adhesion to the glass body, with the outer layer acting as main conductor for the electrodes or as a seed for subsequent plating. Examples of adhesion layers include Cr, Ti, titanium tungsten (TiW) and niobium (Nb). Examples of outer layers include Pd, Ni, Ru, Ag, Pt, Ti, Au, ITO, Mo, Cu, and Al, as well as alloys and combinations thereof. The total thickness of the conductive thin film can be between about 0.1 and 5 microns in some implementations. In implementations in which a conductive thin film provides the sole conductive material of the sidewall electrode, the film may be deposited to a thickness between about 0.1 and 5 microns, such as 1 micron or 2 microns. In implementations in which a conductive thin film is a seed layer for a plating process, it may be deposited to a thickness of about 0.1 to 0.2 microns.

The conductive thin film is continuous and conformally coats any unmasked regions of the glass body, including top and sidewall surfaces of the glass body. In some implementations, other sidewall surfaces of the glass body can be coated. For example, sidewall surfaces of through-glass via holes can be coated to form through-glass via interconnects. According to one implementation, the bottom surface of the glass body may or may not be coated with the conductive thin film in block 204. For example, in an ALD process, if the bottom surface rests on a chuck or other wafer support, it may be inaccessible to the ALD reactants and be left uncoated.

In some implementations, the glass body is unmasked during block 204. In some other implementations, one or more regions of the glass body can be masked during block 204 to prevent or limit formation of a conductive thin film on those regions. For example, in some implementations, electrical isolation regions between support structure segments may be masked. In some implementations, it may not be necessary to mask electrical isolation regions to prevent deposition of a conductive film across the isolation region. For example, in some implementations, the narrow width of an electrical isolation trench can prevent or reduce deposition of a conductive thin film on at least the bottom surface of the electrical isolation trench.

The process 200 continues at block 206 with an optional operation of plating to thicken the conductive thin film. In some implementations, block 206 can include electroplating the conductive thin film to increase its thickness. Block 206 can facilitate narrowing the capacitive gap between sidewall electrodes, thereby increasing the aspect ratio and the transduction signal and efficiency. The thickness of the plated layer may range, for example, from a few microns to hundreds of microns. In some implementations, a plated layer thickness is between about 3 and 30 microns. These thicknesses may be varied depending on the desired implementation and the desired capacitive gap. In some implementations, the resulting capacitive gap can be as small as about 1 micron. Examples of metals that can be plated in block 206 include Cu, Ni and Co, as well as alloys and combinations thereof.

In some implementations, the capacitive gap can be narrowed by depositing a conformal dielectric film at least on the sidewall electrical supports. For example, in some implementations, the glass body can be coated with a conformal dielectric film such as parylene prior to block 204. In some other implementations, the sidewall electrode supports can be conformally coated with a dielectric film after block 204. The top and bottom surfaces of the glass body can be masked to prevent deposition of the dielectric film. The dielectric film can then be covered with a conformal conductive thin film.

FIG. 12D is an example of a schematic illustration of the etched glass body 222 shown in FIG. 12C coated with a conductive thin film 113. The top surfaces of the support structure segments 102a-102h, the movable mass 104, the coupling flexures 106a-106d, and the sidewall electrode support structures 240 as shown in FIG. 12C are covered with the conductive thin film 113. The sidewall surfaces (not shown) of the support structure segments 102a-102h, the movable mass 104, the coupling flexures 106a-106d, and the sidewall electrode support structures 240 as shown in FIG. 12C are also covered with the thin conductive film 113. Covering the sidewall electrode support structures 240 shown in FIG. 12C with the thin conductive film 113 forms the three-dimensional comb-type electrode structures including the four sets of fingers 118e-118h and the four sets of fingers 120e-120h as described above with reference to FIG. 9A.

While there may be some coverage on the sidewall surfaces (not shown) of the trenches of the electrical isolation segments 116a-116h, there is not continuous coverage across the electrical isolation segments 116a-116h. (In some other implementations, some amount of continuous coverage that is insufficient to carry a current or otherwise provide an electrical connection may be present.) FIGS. 13A and 13B show examples of schematic illustrations of an electrical isolation trench at various stages in a manufacturing process. FIG. 13A shows an example of schematic illustrations of top views of the electrical isolation segment 116a prior to and after metallization. A top view 261 of the electrical isolation segment 116a prior to metallization is shown. The electrical isolation segment 116a separates the support structure segments 102a and 102b, forming a trench between the support structure segments 102a and 102b. The trench has a bottom surface 258 and may be formed, for example, during block 202 of the process 200, by exposing the exposed isolation regions 217 shown in FIG. 12B to an etchant. A recess 244 having a width W that extends through the thickness of the glass body may be present due to the etchant reaching the exposed isolation regions 217 from the exposed regions 232 shown in FIG. 12B. Top surfaces 250a and 250b of the support structure segments 102a and 102b, respectively, are glass, as is the bottom surface 258 of the electrical isolation segment 116a. A top view 262 of the electrical isolation segment after metallization is also shown, with the glass top surfaces 250a and 250b of the support structure segments 102a and 102ba covered with conductive thin films 113a and 113b, respectively. The bottom surface 258 of the electrical isolation segment 116a remains as bare glass such that the electrical isolation segment 116a electrically separates the conductive thin film 113a of the support structure segment 102a from the conductive thin film 113b of the support structure segment 102b. According to one implementation, the conductive thin films 113a and 113b may or may not extend down the sidewalls of the electrical isolation segment 116a. FIG. 13B shows an example of a cross-sectional view along line B-B shown in view 262 of FIG. 13A. In the example of FIG. 13B, the electrical isolation segment 116a includes a trench 252 formed in the glass body 222. The trench 252 includes the bottom surface 258 and sidewall surfaces 254. In the example of FIG. 13B, the conductive thin films 113a and 113b extend partially down the sidewalls 254 of the trench 252, though as noted above, in some other implementations, the sidewalls 254 may be substantially free of the conductive thin films 113a and 113b. At least the bottom surface 258 of the trench 252 is substantially free of the conductive thin films 113a and 113b, thereby electrically separating the conductive thin film 113a from the conductive thin film 113b. In some implementations, the width W of the trench 252 is small enough to prevent diffusion of reactants in an ALD, electroless plating, or other diffusion limited process to the bottom surface 258. In a similar manner, the reactants are prevented from diffusing completely through the narrow recess 244. Example trench widths range from about 0.1 to about 5 microns, though the width may vary depending on the particular conductive thin film formation technique employed as well as the depth and profile of the trench 252. It should be noted that while FIG. 13B depicts the trench 252 as having a U-shaped profile, it may have any appropriate profile including a tapered profile, a V-shaped profile, square-shaped profile and the like.

Returning to FIG. 11, the process 200 continues at block 208 with patterning and plating the top and/or bottom surfaces of the metallized glass body. Block 208 can include forming electrodes, bond rings, contact pads and conductive routing on the top and/or bottom surfaces of the glass body. In some implementations, block 208 includes electroplating after defining these or other desired top surface components with a shadow mask. FIG. 9A, described above, is an example of a schematic illustration of the metallized glass body 222 shown in FIG. 12D after plating to define the top movable electrode 108, the top stationary electrodes 110e-110h, the contact pads 112a-112d, and the conductive routing lines 114a-114d.

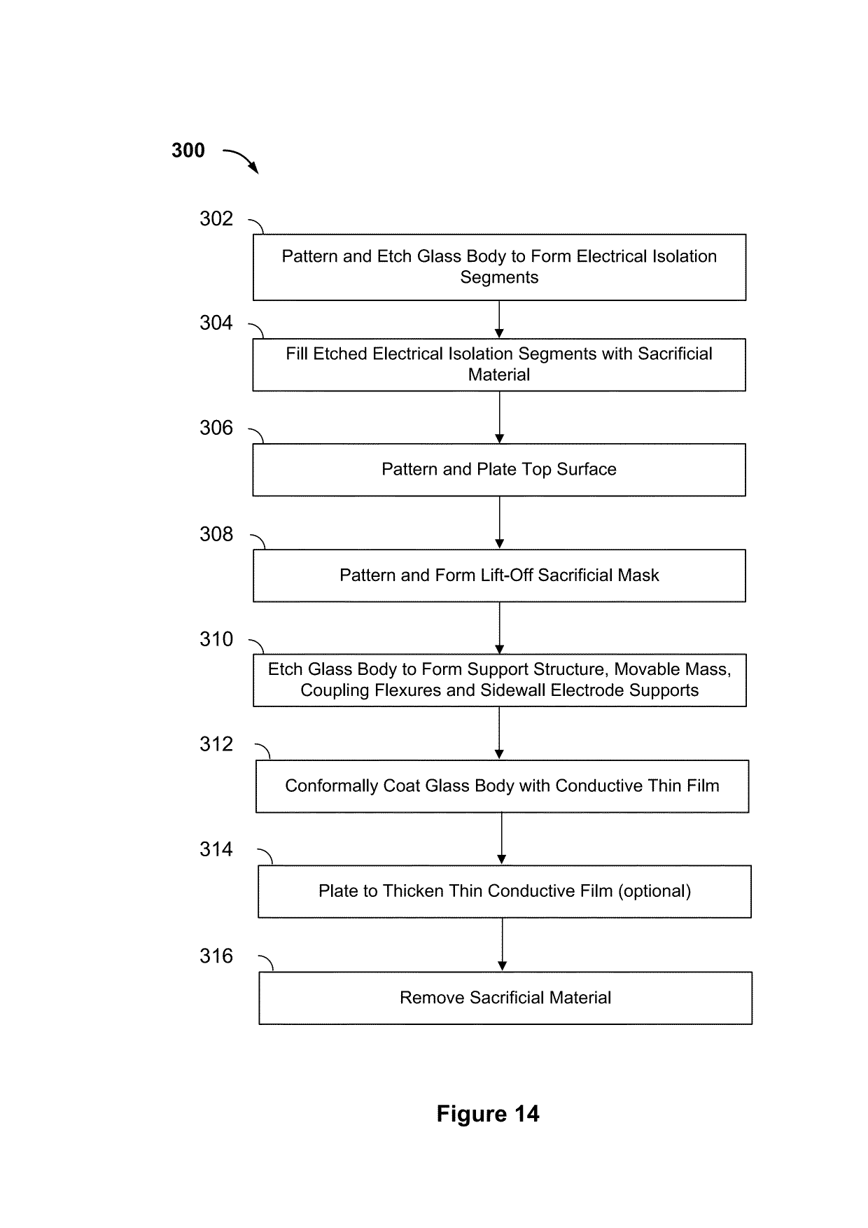

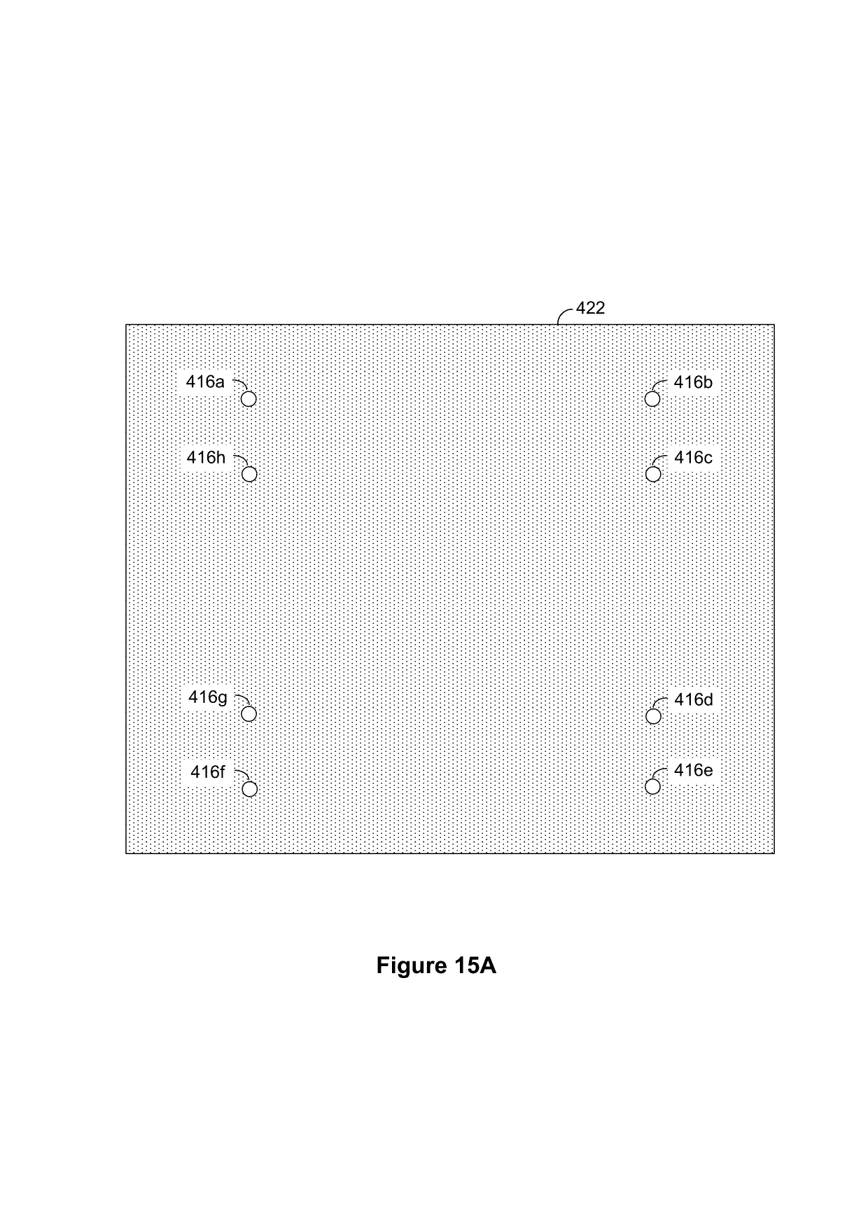

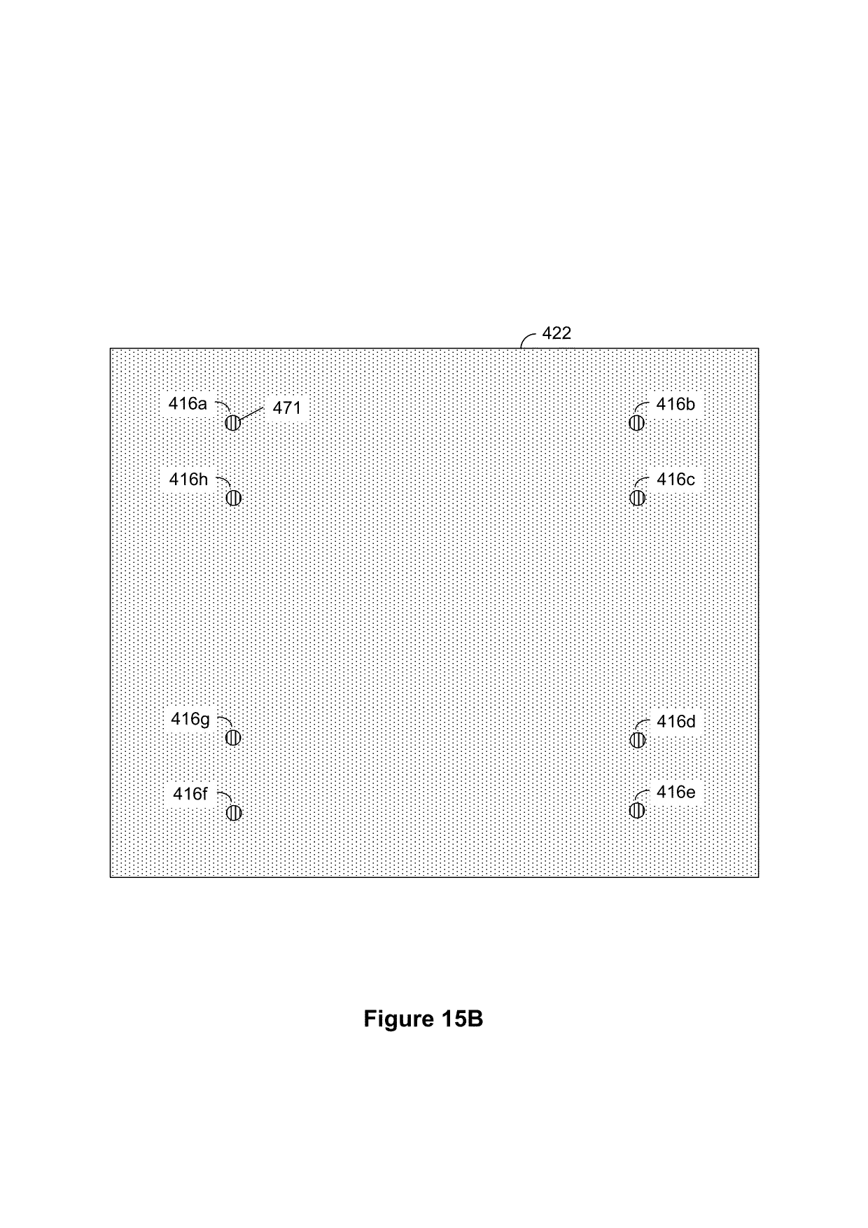

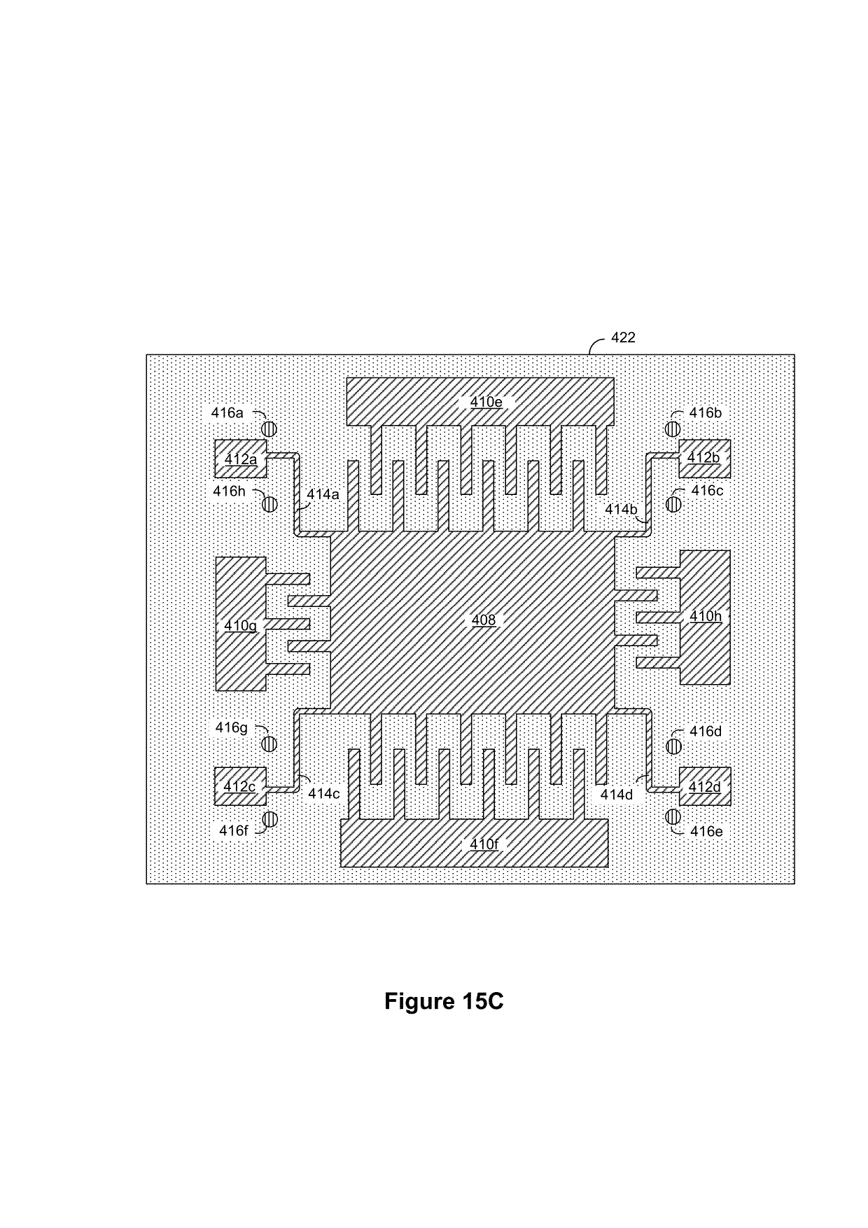

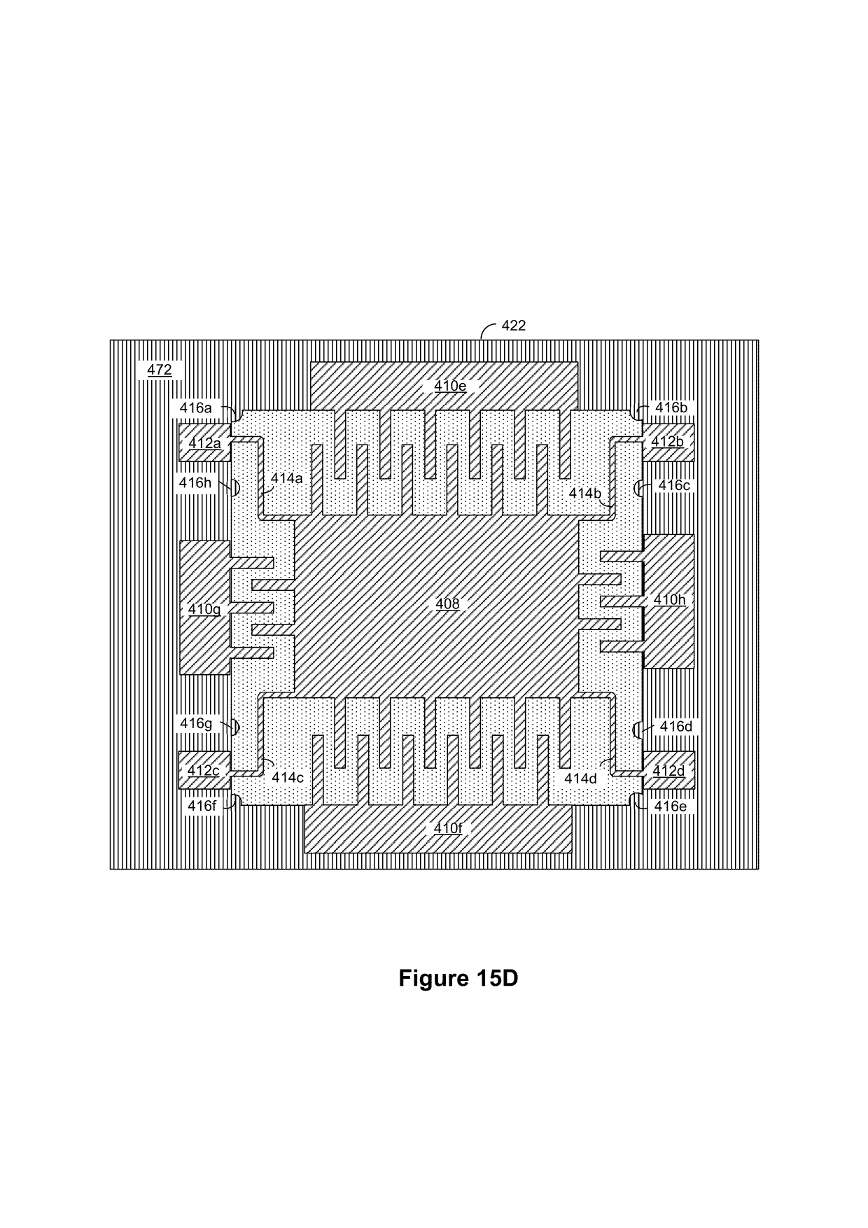

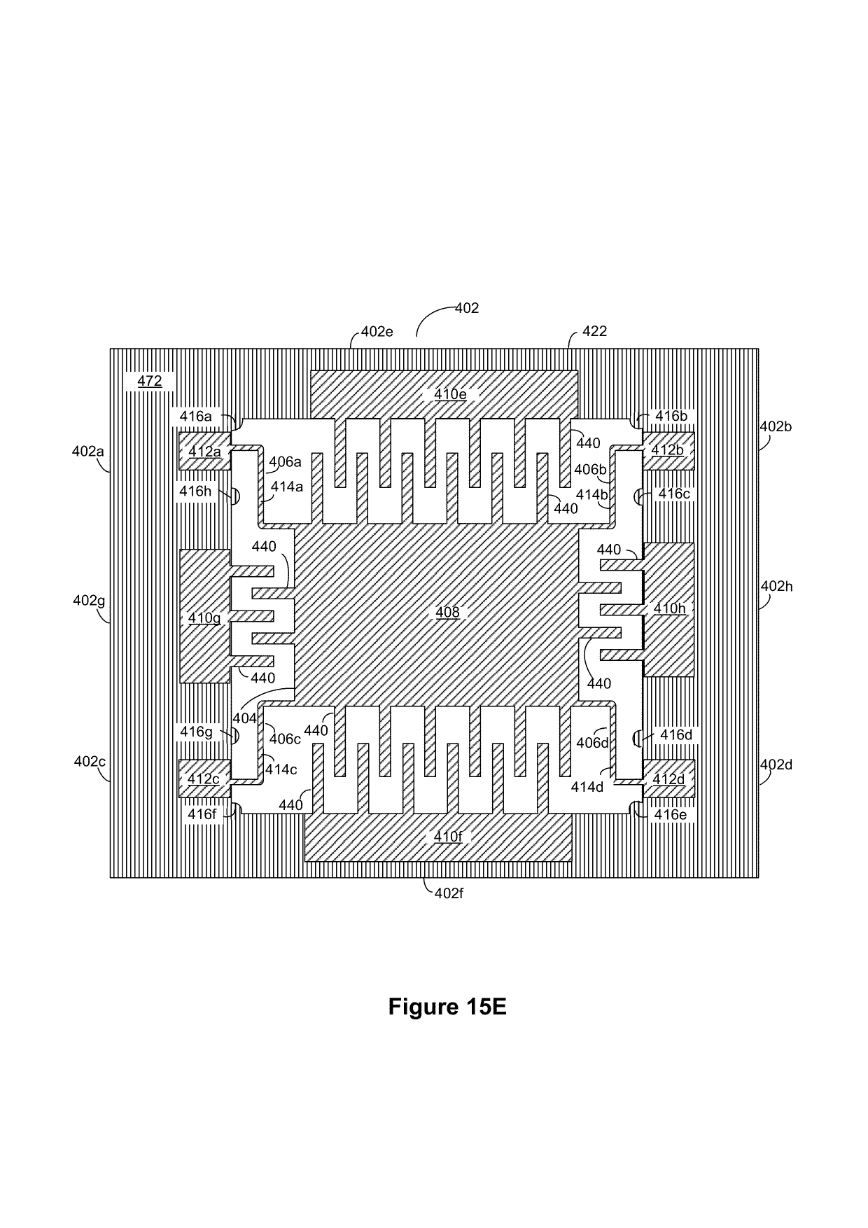

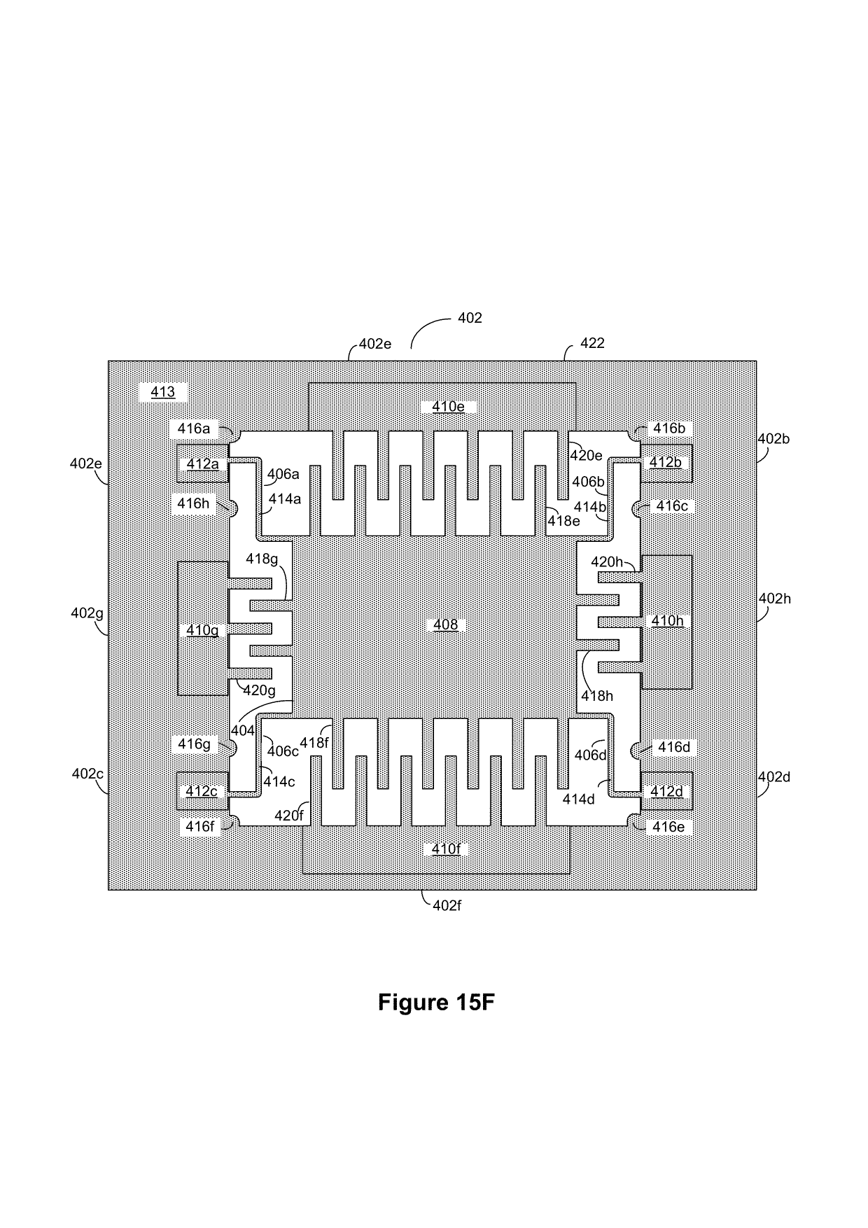

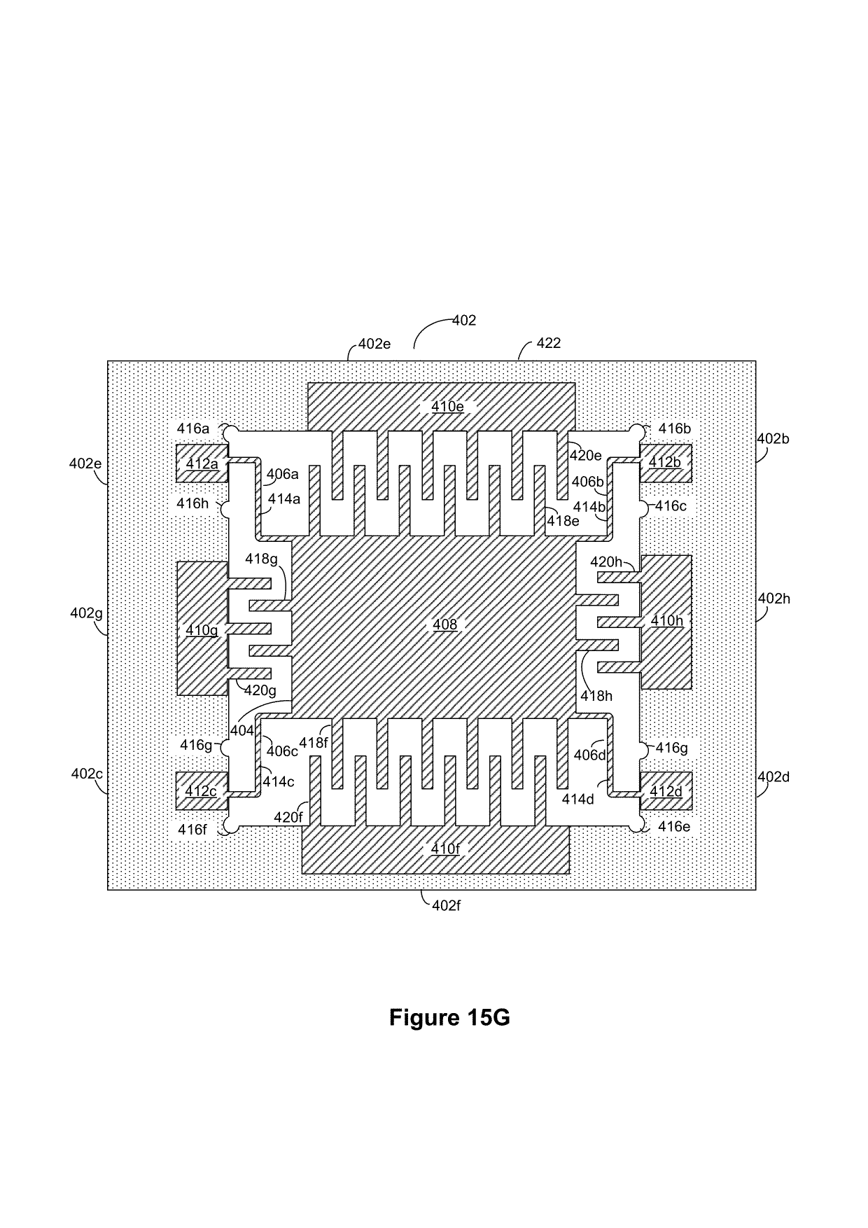

While FIGS. 11-13B describe an example of a manufacturing process for a glass EMS electrostatic structure, various modifications can be made. For example, electrically isolating the support structure segments of a glass EMS electrostatic structure can be performed in a variety of manners according to some implementations. One example is described above with respect to FIGS. 12B-12D, 13A and 13B, in which each of the electrical isolation segments 116a-116h can include a trench in the glass body across which conductive material of the support structure segments does not form. In some implementations, electrical isolation segments can be formed by masking and etching metal deposited in, for example, block 204 of the process 200. In some implementations, the electrical isolation segments can be formed using a sacrificial material to prevent formation of a conductive material between structural support segments. An example of such a process is described below with reference to FIG. 14 and FIGS. 15A-15G. In addition, the order of various operations in FIG. 11 may be modified. For example, in some implementations, top and/or bottom surface metallization may be performed prior to etching the glass body to form the structural support, one or more movable masses, coupling flexures and sidewall electrode supports.

FIG. 14 shows an example of a flow diagram illustrating a manufacturing process for a glass EMS electrostatic structure. FIGS. 15A-15G show examples of schematic illustrations of various stages in a method of making a glass EMS electrostatic structure. First turning to FIG. 14, the process 300 begins at block 302 with patterning and etching the glass body to form electrical isolation segments. In some implementations, the electrical isolation segments can be cavities formed in the glass body, positioned between electrodes and/or contact pads on the support structure. In the process 300, the electrical isolation segments are patterned and etched prior to the formation of other components of the glass EMS electrostatic structure such as the support structure, movable mass, and sidewall electrode supports. The glass body can be a photochemically etchable glass as described above. Block 302 can include masking the glass body to define the electrical isolation segments, exposing the unmasked portions of the glass body to ultraviolet (UV) light and thermal annealing to render them selectively etchable, and selectively etching the unmasked portions to form the electrical isolation segments. In some implementations, electrical isolation segments can be formed by techniques such as laser ablation or sandblasting. FIG. 15A is an example of a schematic illustration of a top view of a glass body including etched electrical isolation segments. Glass body 422 can be a photochemically etched glass substrate, having lateral dimensions ranging from the tens of microns to a few millimeters and a thickness (not shown) ranging from about 50 microns to 1 mm. In some implementations, glass body 422 may be one repeating unit of a larger glass substrate or panel (not shown). The glass body 422 includes etched electrical isolation segments 416a-416h, which are through-glass via holes positioned to electrically separate electrodes and contact pads formed in a subsequent operation. While the example of FIG. 15A depicts the etched electrical isolation segments 416a-416h as being circular, they can be any appropriate shape, including slot-shaped, square-shaped, etc.

Returning to FIG. 14, the process 300 continues at block 304 with filling the etched electrical isolation segments with a sacrificial material. The sacrificial material protects the etched electrical isolation segments during coating of sidewall electrode supports in a subsequent operation. One example of sacrificial material is photoresist. According to various implementations, the etched electrical isolation segments may be filled using a process such as a squeegee-based process, dispensing or direct writing a filler material, screen printing, spray coating, or other appropriate fill process. FIG. 15B is an example of a schematic illustration of a top view of a glass body including the etched electrical isolation segments 416a-416h filled with a sacrificial material 471.

The process 300 continues at block 306 with patterning and plating the top surface of the glass body to form, for example, top electrodes, contact pads and conductive routing. In some implementations, a metal bond ring surrounding the movable mass and coupling flexures may be formed. Electroless or electroplating methods may be used to plate the top surface according to the desired implementation. In some implementations, a seed layer may be deposited prior to plating by PVD, CVD, or other appropriate method. Any appropriate metal can be plated including Cu, Ni, Au, Pd, and combinations and alloys thereof. In some implementations, a bottom surface of the glass body can also be patterned and plated. For example, bottom surface metallization such as contact pads, conductive routing, and a bond ring can be patterned and plated according to the desired implementation. In some implementations, the bottom surface metallization and top surface can be plated simultaneously.

FIG. 15C is an example of a schematic illustration of a top view of a glass body including top surface metallization. A top movable electrode 408, top stationary electrodes 410e-410h, contact pads 412a-412d, and conductive routing lines 414a-414d are patterned and plated on the top surface of the glass body 422. The electrical isolation segments 416a-416h are positioned to separate the top stationary electrodes 410e-410h and contact pads 412a-412d. Specifically, the electrical isolation segment 416a is positioned between the top stationary electrode 410e and the contact pad 412a, the electrical isolation segment 416b is positioned between the top stationary electrode 410e and the contact pad 412b, the electrical isolation segment 416c is positioned between the top stationary electrode 410h and the contact pad 412b, the electrical isolation segment 416d is positioned between the top stationary electrode 410h and the contact pad 412d, the electrical isolation segment 416e is positioned between the top stationary electrode 410f and the contact pad 412d, the electrical isolation segment 416f is positioned between the top stationary electrode 410f and the contact pad 412c, the electrical isolation segment 416g is positioned between the top stationary electrode 410g and the contact pad 412c, and the electrical isolation segment 416h is positioned between the top stationary electrode 410g and the contact pad 412a.

After metallizing the top surface of the glass body, the process 300 continues at block 308 with patterning and forming a lift-off sacrificial mask. The lift-off sacrificial mask can be patterned to cover the peripheral regions of the glass body 422, including the peripheral regions of the top surface of the glass body 422. In some implementations, the lift-off sacrificial mask is a photoresist material. In some implementations, the lift-off sacrificial mask formed in block 308 is composed of the same sacrificial material as employed in block 304. In some other implementations, a different sacrificial material can be used. FIG. 15D shows the top surface of the glass body 422 including a lift-off sacrificial mask 472. In the example of FIG. 15D, the lift-off sacrificial mask 472 is the same sacrificial material as fills the electrical isolation segments 416a-416h. The lift-off sacrificial mask 472, the top movable electrode 408, the top stationary electrodes 410e-410h, the contact pads 412a-412d, and the conductive routing lines 414a-414d together can function as an UV-exposure mask, leaving the regions to be etched to form the glass EMS electrostatic structure exposed. The lift-off sacrificial mask 472 covers the peripheral area of the glass body 422 where metal deposition is undesired. In some implementations, the lift-off sacrificial mask 472 can cover all or part of the top surface metallization such as the stationary electrodes 410e-410h and the contact pads 412a-412d.

Returning to FIG. 14, the process 300 continues at block 310 with etching the glass body to form a support structure, one or more movable masses, coupling flexures and sidewall electrode supports. In some implementations, block 310 can include forming through-glass via holes, the sidewalls of which can be metallized in one or more subsequent operations. Block 310 also can include exposing the unmasked portions of the glass body to ultraviolet (UV) light and thermal annealing to render them selectively etchable, and selectively etching the unmasked portions to form the support structure, one or more movable masses, coupling flexures and sidewall electrode supports. FIG. 15E is an example of a schematic illustration of the glass body shown in FIG. 15D after crystallization and selective etching of its exposed regions. The glass body 422 in the example of FIG. 15E includes the support structure 402, a movable mass 404, coupling flexures 406a-406d, the electrical isolation segments 416a-416h, and sidewall electrode support structures 440. The sidewall electrode support structures 440 have substantially vertically straight sidewalls (not shown) that extend through the thickness of the glass body 422. In the example of FIG. 15E, the sidewall electrode support structures 440 are arranged as interdigitated pairs. The support structure 402 is connected to the movable mass 404 by the coupling flexures 406a-406d. The coupling flexures 406a-406d permit the movable mass 404 to move while the support structure 402 remains stationary. The conductive routing lines 414a-414d overlie the coupling flexures 406a-406d. The support structure 402 includes electrically separate, physically connected support structure segments 402a-402h. The support structure segment 402a includes the contact pad 402a, the support structure segment 402b includes the contact pad 412b, the support structure segment 402c includes the contact pad 412c, the support structure segment 402d includes the contact pad 412d, the support structure segment 402e includes the top stationary electrode 410e, the support structure segment 402f includes the top stationary electrode 410f, the support structure segment 402g includes the top stationary electrode 410g, and the support structure segment 402h includes the top stationary electrode 410h. At the stage of fabrication depicted in FIG. 15E, prior to sidewall metallization, the contact pads 412a-412d and the top stationary electrodes 410e-410h are electrically isolated from each other. As described further below, after sidewall metallization, the electrical isolation segments 416a-416h electrically separate the contact pads 412a-412d and the top stationary electrodes 410e-410h.

The process 300 continues with conformally coating the glass body with a conductive thin film at block 312. Block 312 may be performed using any appropriate conformal deposition process including ALD or electroless plating and results in the sidewalls of the etched glass body covered with a conductive thin film. In addition to forming sidewall electrodes, in some implementations, block 312 can include forming through-glass via interconnects by conformally coating the sidewalls of through-glass via holes with a conductive thin film. Examples of films that can be formed in block 312 include Pd, Ni, Ru, Ag, Cu, as well as alloys and combinations thereof. Block 312 may or may not include deposition on a bottom surface of the glass body depending on the desired implementation. FIG. 15F is an example of a schematic illustration of the etched glass body 422 shown in FIG. 15E coated with a conductive thin film 413. The conductive thin film 413 covers every accessible surface of the glass body 422, including the lift-off sacrificial mask 471 and the sidewall electrode supports structures 440 that are shown in FIG. 15E, the top stationary electrodes 410e-410h, the contact pads 412a-412d, the movable electrode 408, the conductive routing lines 414a-414d and the electrical isolation segments 416a-416h that are filled with a sacrificial material. Covering the sidewall electrode support structures 440 that are shown in FIG. 15E with the thin conductive film 413 forms the three-dimensional comb-type electrode structures including four sets of fingers 418e-418h and the four sets of fingers 420e-420h, similar to the four sets of fingers 118e-118h and 120e-120h as described above with reference to FIG. 9A.

In some implementations, the conductive thin film can be a bilayer including an adhesion layer and an outer layer. The adhesion layer promotes adhesion to the glass body, with the outer layer acting as main conductor for the electrodes or as a seed for subsequent plating. Examples of adhesion layers include Cr, Ti, TiW and Nb. Examples of outer layers include Pd, Ni, Ru, Ag, Pt, Ti, Au, ITO, Mo, Cu, and Al, as well as alloys and combinations thereof.

The total thickness of the conductive thin film can be between about 0.1 and 5 microns according to some implementations. In implementations in which a conductive thin film provides the sole conductive material of the sidewall electrode, the film may be deposited to a thickness between about 0.1 and 5 microns, such as 1 micron or 2 microns. In implementations in which a conductive thin film is a seed layer for a plating process, it may be deposited to a thickness of about 0.1 to 0.2 microns.

Returning to FIG. 14, after conformally coating the glass body with a thin conductive film, the process 300 continues at block 314 with an optional operation of plating to thicken the conductive thin film. In some implementations, block 314 can include electroplating the conductive thin film to increase its thickness. Block 314 can facilitate narrowing the capacitive gap between sidewall electrodes, thereby increasing the aspect ratio and the transduction signal and efficiency. The thickness of the plated layer may range, for example, from a few microns to hundreds of microns. In some implementations, a plated layer thickness is between about 3 and 30 microns. These thicknesses may be varied depending on the desired implementation and the desired capacitive gap. In some implementations, the resulting capacitive gap can be as small as about 1 micron.

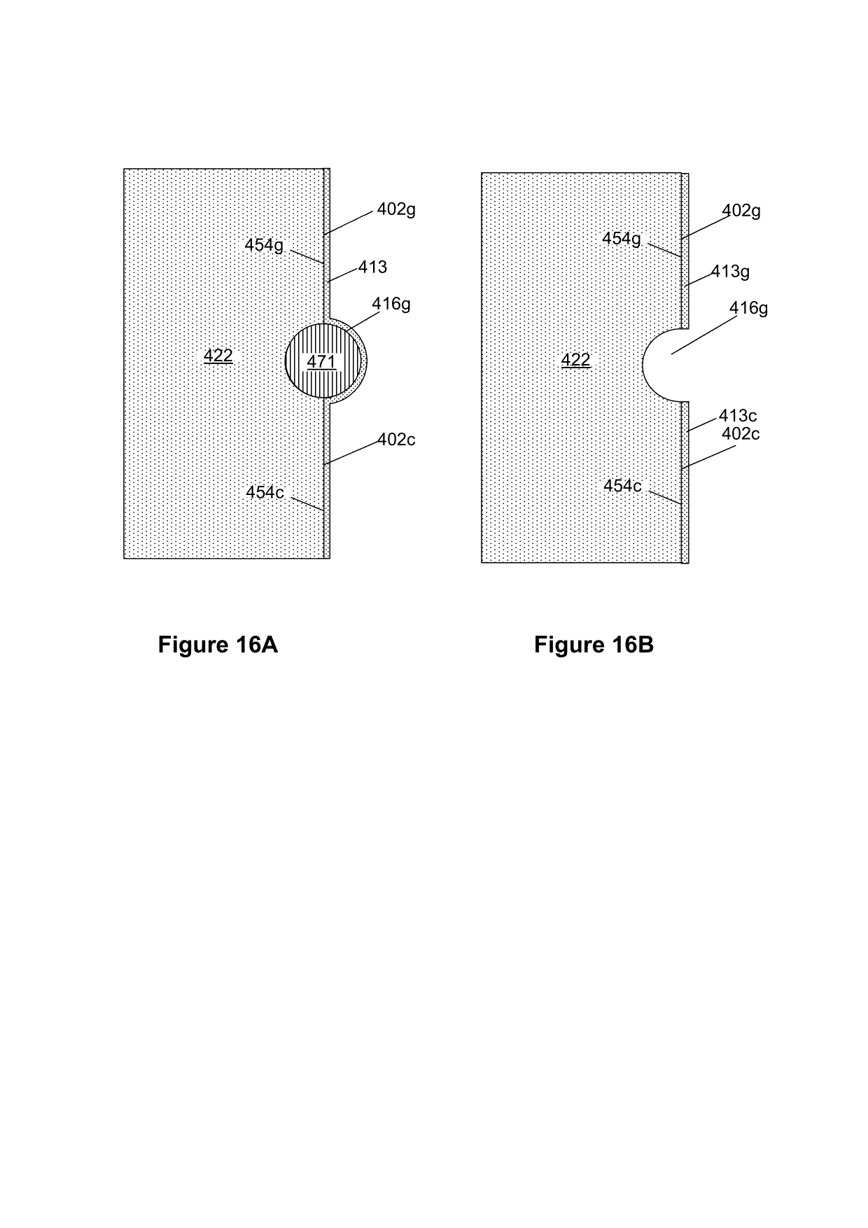

Once the sidewall electrodes are formed in block 312 and, if performed, block 314, the process 300 continues at block 316 with removing the sacrificial material formed in blocks 304 and 308. Block 316 can involve plasma etching, wet etching, or other appropriate removal process. FIG. 15G shows an example of a schematic illustration of a top view of the glass EMS electrostatic structure shown in FIG. 15F after the sacrificial material is removed. The glass body 422 includes the support structure 402 and the movable mass 404, with the support structure 402 divided into electrically isolated, physically connected support structure segments 402a-402h. The support structure 402 is connected to the movable mass 404 by coupling flexures 406a-406d, which permit the movable mass 104 to move while the support structure 402 remains stationary. A plated conductor is patterned to define the top movable electrode 408, the top stationary electrodes 410e-410h, the contact pads 412a-412d, and the conductive routing lines 414a-414d. The conductive routing lines 414a-414d provide conductive pathways between the top movable electrode 408 and the contact pads 412a-412d. The support structure segments 402a-402h are electrically separated from one another by electrical isolation segments 416a-416h as described further below with respect to FIGS. 16A and 16B.

Four sets of fingers 418e-418h extend from the movable mass 404, one set from each side of the movable mass 404, with four sets of fingers 420e-420h extending from the support structure 402, one set each from support structure segments 402e-402h. The glass EMS electrostatic structure includes four three-dimensional comb-type interdigitated electrode pairs. The sidewall surfaces (not shown) of each of the eight sets of fingers 418e-418h and 420e-420h are conductive, forming a three-dimensional comb-type electrode structure, with the eight comb-type electrode structures forming four three-dimensional comb-type interdigitated electrode pairs. The fingers 418e and 420e form a three-dimensional interdigitated electrode pair, the fingers 418f and 420f form a three-dimensional interdigitated electrode pair, the fingers 418g and 420g form a three-dimensional interdigitated electrode pair, and the fingers 418h and 420h form a three-dimensional interdigitated electrode pair. The four comb-type electrode structures formed by the four sets of fingers 418e-418h are electrically connected to the top movable electrode 408. The four comb-type electrode structures formed by each of the sets of fingers 420e-420h are electrically connected to the top stationary electrodes 410e-410h and are electrically isolated from each other by the electrical isolation segments 416a-416h.

In some implementations, the movement of the movable mass 404 can result in a change in the distance between the electrodes of one or more electrode pairs, which can be measured by a resulting change in the capacitance between the electrodes of one or more electrode pairs. In some implementations, application of a voltage difference across the electrodes of an electrode pair can result in a deflection of the movable mass 404 by electrostatic forces. The top movable electrode 408 and thus the comb-type electrode structures formed by each set of fingers 418e-418h can be addressed by the contact pads 412a-412d. The comb-type electrodes formed by each set of fingers 420e-420h can be addressed by the top stationary electrodes 410e-410h, respectively. In some implementations, the plated conductor of the top stationary electrodes 410e-410h extends to the edges and down the sidewall surfaces of the fingers 120e-120h, with the sidewall surfaces also plated. The support structure 402, including the support structure segments 402a-406h, the movable mass 404, the coupling flexures 406a-406d, and the fingers 418e-418h and 420e-420h are formed from a single glass body, with the support structure 402, the movable mass 404, the coupling flexures 406a-406d, and the fingers 418e-418h and 420e-420h extending through the entire thickness of the glass body.

As indicated above, the electrical isolation segments 416a-416h electrically isolate the support structure segments 402a-402h. FIGS. 16A and 16B show examples of schematic illustrations of plan views of an electrical isolation segment at various stages in a manufacturing process. Specifically, FIGS. 16A and 16B show the electrical isolation segment 416g at point midway through the thickness of the glass body 422. The electrical isolation segment 416g is positioned between the support structure segments 402c and 402g of the glass body 422, a portion of which are shown in FIGS. 16A and 16B. FIG. 16A shows the electrical isolation segment 416g filled with the sacrificial material 471. The thin conductive film 413 conformally coats the exposed sidewall surface of the sacrificial material 471 and sidewall surfaces 454c and 454g that extend through the thickness (not shown) of the glass body 422. FIG. 16B shows the electrical isolation segment 416g after removal of the sacrificial material 471 shown in FIG. 16A. The portion of the conductive thin film 413 covering the sacrificial material 471 in FIG. 16A is removed with the sacrificial material 471, such that the electrical isolation segment 416g separates the conductive thin films 413c and 413g of the support structure segments 402a and 402g, respectively. In this manner, the electrical isolation segment 416g electrically separates the support structure segments 402c and 402g, thereby separating the contact pad 412c shown in FIG. 15G from the top stationary electrode 410g.

While FIGS. 11-16B show examples of glass EMS electrostatic structures and methods of manufacturing glass EMS electrostatic structures, various modifications may be made. For example, in some implementations, a glass EMS electrostatic structure can include one or more through-glass via interconnects. Through-glass via interconnects can be positioned on the peripheral region of a glass EMS electrostatic structure, for example. In some implementations, a glass EMS electrostatic structure can include a metal bond ring configured to join to a lid.

Once a glass EMS electrostatic structure is formed, for example as described above with respect to FIGS. 11-16B, it can be singulated if necessary from a large glass substrate including multiple glass electrostatic devices. The individual dies, each including a glass EMS electrostatic structure, for example as shown in the example of FIG. 9A or FIG. 15G, can be further packaged, for example with an application specific integrated circuit (ASIC) on a silicon chip. Packaging can protect the functional units of a system from the environment, provide mechanical support for the system components, and provide an interface for electrical interconnections.

FIGS. 17A-17C show examples of schematic illustrations of a packaged die including a glass EMS electrostatic device. FIG. 17A shows a die 500 including an interior etched portion 501 of a glass EMS electrostatic structure. The interior etched portion 501 of the glass EMS electrostatic structure includes sidewall electrodes 522, which are connected to surface metallization pads 586, and can include other etched components such as a movable mass and coupling flexures. The surface metallization pads 586 can be contact pads or surface electrodes, for example. The die 500 is covered by a lid 582, which can be any appropriate type of lid including a glass lid. The lid 582 can be joined to the die 500, for example by a solder bond (not shown) to a metal bond ring, and can protect the functional components of the glass EMS electrostatic structure. In the example depicted in FIG. 17A, the lid 582 includes a cavity 584 that overlies the interior etched portion 501 of the glass EMS structure. In some implementations, the lid 582 does not include the cavity 584 and can lie flush against the die 500. The die 500 is electrically connected to a silicon chip 580 by flip-chip bonds 590, which connect to the surface metallization pads 586. In some other implementations, the die 500 can be electrically connected to the silicon chip 580 by any appropriate bonds including wire bonds or by anisotropic conductive film (ACF). The package including the die 500 with a glass EMS electrostatic structure electrically connected to the silicon chip 580 can be mounted on a printed circuit board (PCB), for example.

FIG. 17B shows a die 500 including interior etched portion 501 of a glass EMS electrostatic structure and a through-glass via interconnect 591. The interior etched portion 501 includes sidewall electrodes 522, which are connected to surface metallization pads 586. The glass EMS electrostatic structure can also include other components such as a movable mass, support structure, and coupling flexures as described above. The through-glass via interconnect 591 includes a conductive sidewall 593 (shown in cross-section), also connected to a surface metallization pad 586. As in the example of FIG. 17A, the die 500 is covered by a lid 582 that protects the functional components of the glass EMS electrostatic structure, with a cavity 584 that covers the interior etched portion 501. The die 500 is electrically connected to pads (not shown) on an integration substrate 595 by flip-chip bonds 590. In some other implementations, the die 500 can be electrically connected to the silicon chip 580 by any appropriate bonds including wire bonds or by ACF. The integration substrate 595 can be for example, a glass or silicon interposer substrate. Integration substrate 595 includes through-substrate via interconnects 596, which provide a conductive pathway through it. In some implementations, for example, the through-substrate via interconnects 596 can be through-glass via interconnects formed by sandblasting and plating via holes through a glass substrate. Solder balls 573 are shown attached to the integration substrate 595 and are configured to electrically connect the die 500, via the flip-chip bonds 590 and the through-substrate via interconnects 596, to a PCB or other appropriate substrate.

As indicated above, in some implementations, a glass EMS electrostatic structure can include double sided patterned and plated surface components such as electrodes and contact pads. FIG. 17C shows an example of a die 500 including an interior etched portion 501 of a glass electrostatic EMS structure and through-glass via interconnects 591. The through-glass via interconnects 591 include conductive sidewalls 593 (shown in cross-section) that are connected to bottom-side surface metallization pads 586a. The through-glass via interconnects 591 can be electrically connected to the functional components of the glass electrostatic EMS structure including sidewall electrodes 522 by conductive routing (not shown). In the example of FIG. 17C, the through-glass via interconnects 591 provide an electrical connection to an integration substrate 595 through flip-chip bonds 590a. As in the example of FIG. 17B, the integration substrate 595 includes through-substrate via interconnects 596, which provide a conductive pathway through it. Solder balls 573 are shown attached to the integration substrate 595 and are configured to electrically connect the die 500, via the flip-chip bonds 590 and the through-substrate via interconnects 596, to a PCB or other appropriate substrate. The die 500 is also electrically connected to a silicon chip 580 through top-side surface metallization pads 586b and flip-chip bonds 590b.

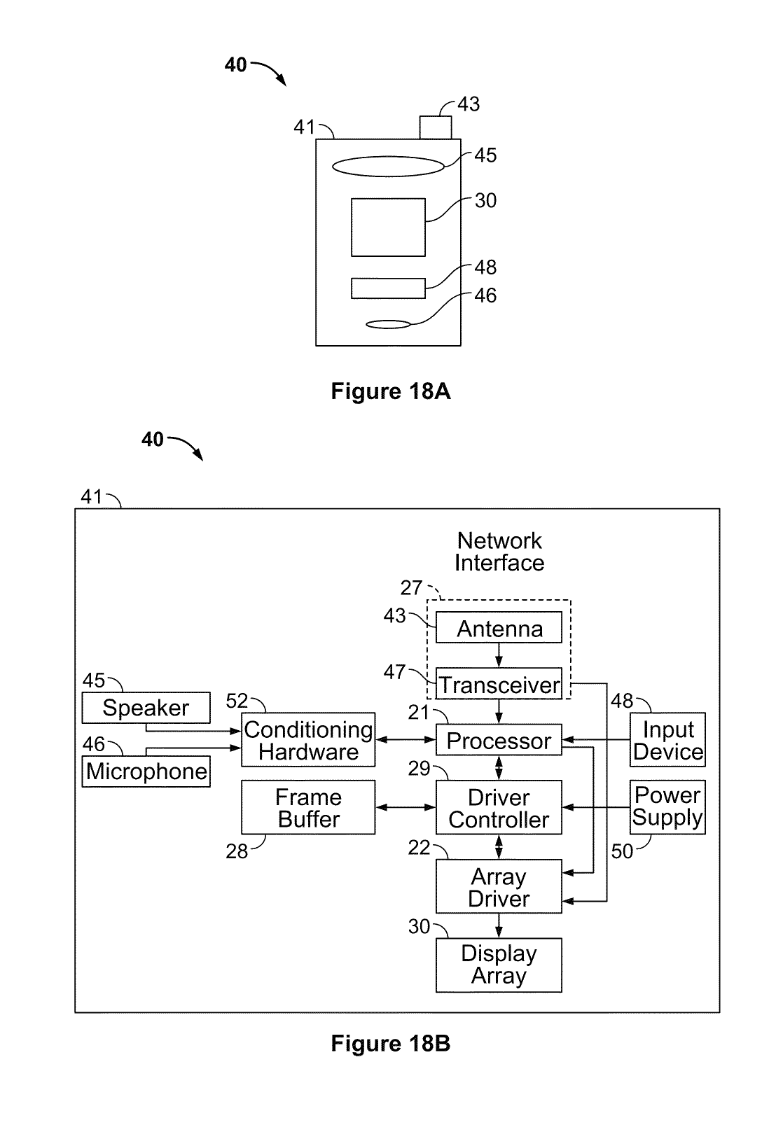

In some other implementations, the glass EMS electrostatic devices described herein can be compatible with displays and other devices that are also fabricated on glass (or other transparent) substrates, with the non-display devices fabricated jointly with a display device or attached as a separate device, the combination having well-matched thermal expansion properties. For example, a device such as a smart phone, tablet, e-reader, or portable media player may include one or more of a gyroscope, accelerometer or other non-display glass EMS electrostatic device. In such a smart phone, tablet, e-reader, portable media player, etc., the glass EMS electrostatic device can be configured to communicate data to a processor (such as processor 21 of FIG. 18B, below).

FIGS. 18A and 18B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 18B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a glass body including a movable mass, a support structure, and a plurality of sidewalls; and
one or more electrode pairs formed on the plurality of sidewalls, wherein the movable mass and the support structure are capacitively coupled by the one or more electrode pairs such that movement of the movable mass is detectable by a change in capacitance between one or more electrode pairs and/or movement of the movable mass can be induced by application of an electrostatic force to one or more electrode pairs.

2. The apparatus of claim 1, wherein the plurality of sidewalls extend through the glass body.

3. The apparatus of claim 1, wherein the height of each sidewall is between about 50 microns and 1 mm.

4. The apparatus of claim 1, wherein a gap between electrodes in a pair of the one or more electrode pair is no more than about 2 microns.

5. The apparatus of claim 1, wherein each of the one or more electrode pairs is an interdigitated electrode pair.

6. The apparatus of claim 1, wherein the glass body further includes flexures attaching the movable mass to the support structure.

7. The apparatus of claim 6, wherein at least one of the flexures is S-shaped or U-shaped.

8. The apparatus of claim 6, wherein the flexures have a length of at least about 50 microns.

9. The apparatus of claim 1, wherein the apparatus is an electromechanical systems (EMS) electrostatic sensor.

10. The apparatus of claim 1, wherein the movable mass includes a plurality of coupled masses.

11. The apparatus of claim 1, wherein the sidewalls are substantially planar.

12. The apparatus of claim 1, wherein the glass body is a photochemically etched glass substrate.

13. The apparatus of claim 1, further comprising one or more through-glass via interconnects that extend through the glass body.

14. The apparatus of claim 1, further comprising a lid that covers at least the movable mass and the one or more electrode pairs.

15. The apparatus of claim 1, further comprising a silicon chip in electrical communication with the one or more electrode pairs.

16. The apparatus of claim 1, further comprising a substrate bonded to the glass body, wherein the substrate includes through-substrate via interconnects.

17. A system comprising the apparatus of claim 1, the system further comprising:
a display;
a processor that is configured to communicate with the display, the processor being configured to process image data; and
a memory device that is configured to communicate with the processor.

18. The system of claim 17, further comprising:
a driver circuit configured to send at least one signal to the display; and
a controller configured to send at least a portion of the image data to the driver circuit.

19. The system of claim 17, further comprising:
an image source module configured to send the image data to the processor.

20. The system of claim 19, wherein the image source module includes at least one of a receiver, transceiver, and transmitter.

21. The system of claim 17, further comprising:
an input device configured to receive input data and to communicate the input data to the processor.

22. A method comprising:
masking a glass substrate;
treating unmasked areas of the glass substrate;
etching the treated areas of the glass substrate to form a glass body including a movable mass, a support structure, and one or more pairs of sidewall electrode supports, each pair including a plurality of sidewalls; and
conformally coating the sidewalls of each pair of sidewall electrode supports with a conductive thin film to form one or more pairs of sidewall electrodes.

23. The method of claim 22, wherein a plurality of electrically separated sidewall electrodes are formed.

24. The method of claim 22, wherein etching the treated areas of the glass substrate includes forming one or more pairs of interdigitated sidewall electrode supports.

25. The method of claim 22, further comprising plating contacts pads and surface electrodes on a top surface of the glass body.

26. The method of claim 22, wherein etching the treated areas of the glass substrate includes partially etching the glass substrate to form one or more trenches in the glass body.

27. The method of claim 26, wherein conformally coating the sidewalls of each pair of electrode supports with a conductive thin film includes leaving at least a bottom surface of each trench uncoated.

28. The method of claim 22, further comprising etching the glass substrate to define electrode isolation regions and filling the electrode isolation regions with a sacrificial material.

29. The method of claim 28, further comprising removing the sacrificial material after conformally coating the sidewalls with the conductive thin film.

30. The method of claim 22, further comprising plating the conductive thin film to narrow a gap between adjacent sidewall electrodes.

31. The method of claim 22, further comprising etching the treated areas of the glass substrate to form a plurality of glass bodies each including movable mass, a support structure, and one or more pairs of sidewall electrode supports.
